(19) United States
(12) Patent Application Publication
(10) Pub. No.: US 2026/0068488 A1
(43) Pub. Date: Mar. 5, 2026

(54) Display Device and Method for Fabricating the Same

(71) Applicant: LG Display Co., Ltd., Seoul (KR)

(72) Inventors: Kyung Jae Yoon, Paju-si (KR); Seung Han Paek, Paju-si (KR); Jeon Phill Han, Paju-si (KR); Yu Cheol Yang, Paju-si (KR); Nam Woo Kim, Paju-si (KR)

(21) Appl. No.: 18/986,624

(22) Filed: Dec. 18, 2024

(30) Foreign Application Priority Data
Sep. 5, 2024 (KR) 10-2024-0120776

(51) Int. Cl. H10K 59/80; H10K 59/12

(52) U.S. Cl. CPC H10K 59/873; H10K 59/1201; H10K 59/8792

(57) ABSTRACT

Embodiments disclose a display device and a method of fabricating the same, the display device including a substrate having a plurality of pixels disposed on one surface and including a side surface as an etching surface, and an organic film disposed on the other surface opposite to the one surface of the substrate and including a plurality of etching patterns at a position corresponding to the etching surface.

### CROSS-REFERENCE TO RELATED APPLICATION

This application claims priority to and the benefit of Republic of Korea Patent Application No. 10-2024-0120776, filed in the Republic of Korea on Sep. 5, 2024, which is hereby incorporated by reference in its entirety.

### 1. TECHNICAL FIELD

The present specification relates to a display device and a method of fabricating the same.

### 2. DISCUSSION OF RELATED ART

Display devices include various light-emitting devices, such as a liquid crystal display (LCD) device or an organic or inorganic light-emitting device, within a display area. Such a display device may include, on a glass substrate, a display panel having a plurality of light-emitting devices formed thereon and a polarizer film disposed on the display panel.

Generally, when a substrate is etched to separate a plurality of display devices provided on the substrate, an etching area of a glass substrate is determined using laser processing of a mask film. In such a case, since the mask film is patterned using laser, slight errors occur in terms of position precision.

### SUMMARY

Therefore, the inventors of the present disclosure recognized the problems mentioned above and other limitations associated with the related art, and conducted various experiments to implement a display device and a method of fabricating the same capable of improving position precision when etching a substrate using a plurality of etching patterns formed on an organic film and adjusting an etching shape of an etching surface in an etching area of a substrate.

Embodiments of the present specification are not limited to the above-mentioned aspect, and other unmentioned aspects should be clearly understood by those of ordinary skill in the art from the description below.

To achieve these and other embodiments of the inventive concepts, as embodied and broadly described herein, a display device may include a substrate having a plurality of pixels disposed on one surface and including a side surface as an etching surface, and an organic film disposed on the other surface opposite to the one surface of the substrate and including a plurality of etching patterns at a position corresponding to the etching surface.

Another embodiment of the present disclosure is to provide a method of fabricating a display device, the method including forming a plurality of display cells on one surface of a substrate, forming an organic film on the other surface opposite to the one surface of the substrate, forming a plurality of etching patterns by patterning the organic film, and forming an etching groove along an etching area by etching the substrate below the plurality of etching patterns.

According to the present disclosure, by etching an organic film disposed on the other surface of the substrate to form a plurality of etching patterns, and then using the etching patterns as etching masks to etch a portion of the substrate that is located in an etching area, precision with respect to etching positions on the substrate can be improved in comparison to a laser process.

According to the present disclosure, by forming a side coating film on an etching surface of a substrate, light leakage can be prevented or reduced, and edges of a display panel can be prevented or obviated from being visible.

According to the present disclosure, since it is possible to control an etching surface of a substrate by adjusting the widths of etching holes between etching patterns of an organic film, the stiffness of the etching surface of the substrate can be improved, and accidents in which a worker is injured by a sharp etching surface can be prevented or reduced.

According to the present disclosure, by forming an organic film on the other surface of a substrate to define an etching area for cutting the substrate, damage to the substrate can be prevented or reduced, and transmission of external impact to a display panel can be prevented or reduced.

According to the present disclosure, since an organic film having a plurality of etching patterns is formed on the other surface of a substrate and thus it is not necessary to form a separate side coating film, the fabrication process and costs can be reduced.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other embodiments, features, and effects of the present specification will become more apparent to those of ordinary skill in the art by describing exemplary embodiments thereof in detail with reference to the accompanying drawings, in which:

FIG. 1 is a perspective view showing a display device according to an example embodiment of the present specification;

FIG. 2 is a view schematically showing an example configuration of a display panel of FIG. 1 according to an example embodiment of the present specification;

FIG. 3 shows an example of a cross-sectional view along line I-I′ of FIG. 1 according to an example embodiment of the present specification;

FIG. 4 is a flowchart showing a method of fabricating a display device according to an example embodiment of the present specification;

FIGS. 5A to 5L are cross-sectional views showing the method of fabricating the display device according to an example embodiment of the present specification;

FIG. 6 is a cross-sectional view showing a substrate etching form of a display panel according to an example embodiment of the present specification;

FIG. 7 is a cross-sectional view showing a substrate etching form of a display panel according to an example embodiment of the present specification;

FIG. 8 is a cross-sectional view showing a substrate etching form of a display panel according to an example embodiment of the present specification;

FIG. 9 is a cross-sectional view showing a substrate etching form of a display panel according to an example embodiment of the present specification;

FIG. 10 is a cross-sectional view showing a substrate etching form of a display panel according to an example embodiment of the present specification;

FIGS. 11A to 11C are cross-sectional views showing a process of etching a substrate of the display panel according to an example embodiment of the present specification;

FIGS. 12A to 12C are cross-sectional views showing a process of etching a substrate of the display panel according to an example embodiment of the present specification;

FIGS. 13A to 13C are cross-sectional views showing a process of etching a substrate of the display panel according to an example embodiment of the present specification;

FIGS. 14A to 14C are cross-sectional views showing a process of etching a substrate of the display panel according to an example embodiment of the present specification; and

FIGS. 15A to 15C are cross-sectional views showing a process of etching a substrate of the display panel according to an example embodiment of the present specification.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and a method of achieving the same should become clear with example embodiments described in detail below with reference to the accompanying drawings. However, the present disclosure is not limited to the example embodiments disclosed below and may be implemented with a variety of different forms. The example embodiments are merely provided to allow those skilled in the art to completely understand the scope of the present disclosure, and the present disclosure is defined only by the scope of the claims.

The figures, shapes, dimensions, ratios, angles, numbers, and the like disclosed in the drawings for describing the various example embodiments of the present disclosure are merely illustrative and are not limited to matters shown in the present disclosure. Like reference numerals refer to like elements throughout. Further, in describing the present disclosure, detailed descriptions of well-known technologies will be omitted or may be briefly provided when it is determined that they may unnecessarily obscure the gist of the present disclosure. Any implementation described herein as an “example” is not necessarily to be construed as preferred or advantageous over other implementations.

When ‘including’, ‘having’, and ‘comprising’ mentioned in the present disclosure are used, other parts may be added unless terms such as ‘only’ is used. In the case of expressing a component in a singular form, it includes the case of including the plural unless otherwise specified. In interpreting components, it is interpreted as including an error range or tolerance range even if there is no explicit description of such an error or tolerance range.

In the case of a description of a positional relationship, for example, if the positional relationship of the two parts is described as ‘˜top’, ‘˜upper’, ‘˜bottom’, “lower”, ‘˜side’, etc., one or more other parts may be located between the two parts unless a more limiting term such as “closely”, ‘right’ or ‘direct’ is used. Any element or layer referred to as (on) over or over another layer includes the case of interposing another layer or other element directly on or in the middle of another element. Furthermore, the terms “left,” “right,” “top,” “bottom, “downward,” “upward,” “upper,” “lower,” and the like refer to an arbitrary frame of reference.

In describing a time relationship, for example, when the temporal order is described as for example, “after,” “subsequent,” “next,” and “before,” a case which is not continuous may be included unless a more limiting term, such as “just,” “immediate(ly),” or “direct(ly)” is used.

In addition, although first, second, “A,” “B,” “(a),” “(b),” and the like are used to describe various components, these components are not limited by these terms. For example, the essence, sequence, order, or number of the corresponding elements should not be limited by these terms. These terms are used only to distinguish one component from another. Thus, the first component mentioned below may be the second component within the technical idea of the present disclosure.

Throughout the disclosure, the same reference numerals refer to the same components.

Where an element or layer is referred to as being “on” or “connected to” another element or layer, it should be understood to mean that the element or layer may be directly on or directly connected to the other element or layer, or that intervening elements or layers may be present. Also, where one element is referred to as being disposed “on” or “under” another element, it should be understood to mean that the elements may be so disposed to directly contact each other, or may be so disposed without directly contacting each other.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The size and thickness of each component shown in the drawings are shown for convenience of description and are not necessarily limited to the size and thickness of the component shown in the present disclosure.

Features of each of the various example embodiments of the present disclosure may be partially or entirely coupled or combined with each other, technically various interworking and driving are possible, and each of the embodiments may be independently implemented with respect to each other or may be implemented together in a related relationship.

In the present specification, a pixel circuit and a gate driver formed on a display panel may include a plurality of transistors. The transistors may be implemented with oxide thin film transistors (oxide TFTs) including an oxide semiconductor, low temperature polysilicon (LTPS) TFTs including low temperature polysilicon, and the like. In addition, each of the transistors may be implemented with a p-channel TFT or an n-channel TFT.

The transistor is a three-electrode element including a gate, a source, and a drain. The source is an electrode that supplies carriers to the transistor. Further, the carriers in the transistor start to flow from the source. In addition, the drain is an electrode through which the carriers are discharged from the transistor to the outside. Further, in the transistor, carriers flow from the source to the drain. In the case of an n-channel transistor, since carriers are electrons, a source voltage has a voltage lower than a drain voltage so that the electrons flow from the source to the drain. In this case, in the n-channel transistor, currents flow from the drain to the source. In the case of a p-channel transistor (PMOS), since carriers are holes, a source voltage is higher than a drain voltage so that the holes flow from the source to the drain. Further, in the p-channel transistor, since the holes flow from the source to the drain, currents flow from the source to the drain. It should be noted that the source and drain of the transistor are not fixed in position. For example, the source and drain are interchangeable depending on an applied voltage. Accordingly, the present embodiment is not limited by the source and drain of the transistor. In the following description, the source and the drain of the transistor will be referred to as a first electrode and a second electrode.

Hereinafter, a display device according to various example embodiments of the present specification will be described with reference to the accompanying drawings. In assigning reference numerals to components of each drawing, the same reference numerals may be assigned to the same components wherever possible even when the components are shown in different drawings. Also, in describing the present disclosure, when a detailed description of a related known configuration or function is determined as having the possibility of obscuring the gist of the present disclosure, the detailed description thereof may be omitted.

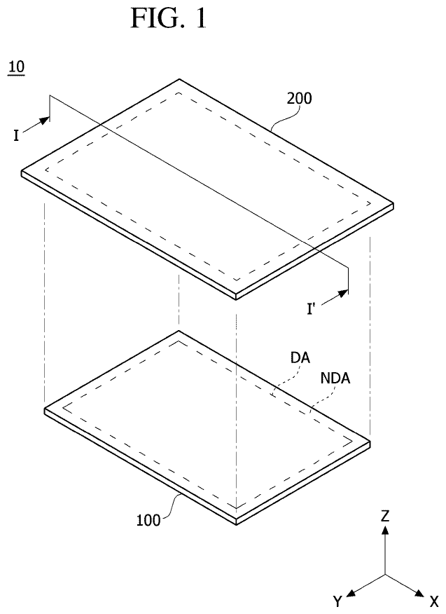

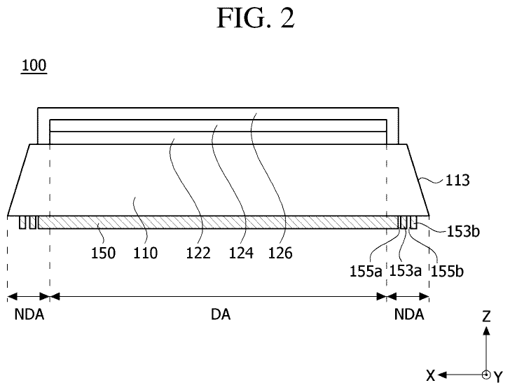

FIG. 1 is a perspective view showing a display device according to an embodiment of the present specification. FIG. 2 is a view schematically showing a configuration of a display panel of FIG. 1 according to an embodiment of the present specification.

Hereinafter, the X-axis indicates a direction parallel to a scan line, the Y-axis indicates a direction parallel to a data line, and the Z-axis indicates a height direction of the display device.

Although a case in which a display device 10 according to an embodiment of the present specification is implemented as an organic light-emitting display device is mainly described herein, the display device 10 may also be an electroluminescence display device, such as a quantum dot light-emitting diode (QLED) display device or a micro light-emitting display device.

As illustrated in FIG. 1, the display device 10 according to an embodiment of the present specification may include a display panel 100 and a cover substrate 200.

The display panel 100 according to one embodiment of the present specification displays an image and may include a substrate 110, a circuit device layer 122, a light-emitting device layer 124, and an encapsulation layer 126 as illustrated in FIG. 2.

The substrate 110 may be a glass substrate that is disposed to face the cover substrate 200. Hereinafter, descriptions will be given assuming that the substrate 110 is a glass substrate. However, the present disclosure is not limited thereto, and the substrate 110 may include glass, plastic, or a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

The circuit device layer 122 is provided on one surface of the substrate 110 that faces the cover substrate 200. A circuit device including various signal lines, a thin film transistor, a capacitor, and the like is provided for each pixel in the circuit device layer 122. The signal lines may include a scan line, a data line, a driving power line, a common power line, and a reference line, but the present disclosure is not limited thereto. The thin film transistor may include a switching thin film transistor, a driving thin film transistor, and a sensing thin film transistor.

The switching thin film transistor serves to be switched according to a scan signal supplied to the scan line and supply a data voltage supplied from the data line to the driving thin film transistor.

The driving thin film transistor serves to be switched according to the data voltage supplied from the switching thin film transistor, generate a data current from power supplied from the driving power line, and supply the data current to a first electrode of each pixel.

The sensing thin film transistor may serve to sense threshold voltage deviation of the driving thin film transistor that becomes a cause of image quality degradation. The sensing thin film transistor supplies current of the driving thin film transistor to the reference line in response to a sensing control signal supplied from a gate line or a separate sensing control line.

The capacitor may serve to maintain the data voltage supplied to the driving thin film transistor during one frame. Accordingly, the capacitor is connected to each of a gate terminal and a source terminal of the driving thin film transistor.

The light-emitting device layer 124 is provided on the circuit device layer 122. The light-emitting device layer 124 includes a plurality of light-emitting devices. The plurality of light-emitting devices each includes first electrodes, a light-emitting layer, and a second electrode. The light-emitting layer may be an organic light-emitting layer including an organic material. In this case, the light-emitting layer may include a hole transporting layer, an organic light-emitting layer, and an electron transporting layer. For example, the light-emitting layer may include one or more of a hole injection layer (HIL), a hole transmitting layer (HTL), an electron transmitting layer (ETL) and an electron injection layer (EIL), but the present disclosure is not limited thereto. When a voltage is applied to the first electrodes and the second electrodes, holes and electrons move to the organic light-emitting layer through the hole transporting layer and the electron transporting layer, respectively, and combine with each other, thereby emitting light.

The light-emitting device layer 124 may be a pixel array layer on which pixels are formed, and thus an area in which the light-emitting device layer 124 is formed may be defined as a display area DA. An area around the display area may be defined as a non-display area NDA. For example, the non-display area NDA may be disposed to be adjacent to the display area DA.

The encapsulation layer 126 is provided on the light-emitting device layer 124. The encapsulation layer 126 serves to prevent or reduce penetration of oxygen or moisture into the light-emitting device layer 124. The encapsulation layer 126 may include at least one inorganic film and at least one organic film. For example, the encapsulation layer 126 may have a structure in which at least one organic film is disposed between inorganic films. The uppermost film of the encapsulation layer 126 may be the inorganic film. For example, an upper surface and a side surface of the encapsulation layer 126 may be covered by the inorganic film.

The cover substrate 200 may be formed of plastic or glass and is disposed on the display panel 100. Although the display panel 100 is illustrated as being a top emission type in FIG. 1, the present specification is not necessarily limited thereto. For example, the cover substrate 200 may be disposed in a direction in which the display panel 100 emits light.

Accordingly, when the display panel 100 is a top emission type, the cover substrate 200 may be disposed above the display panel 100. When the display panel 100 is a bottom emission type, the cover substrate 200 may be disposed below the display panel 100. Hereinafter, for convenience of description, a case in which the display panel 100 is the top emission type will be described.

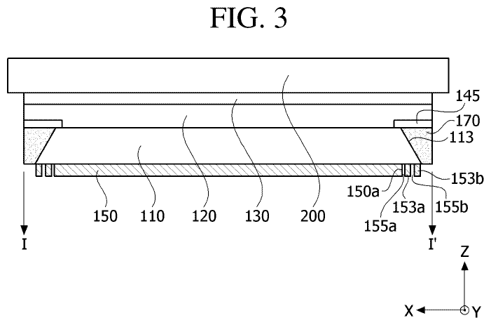

FIG. 3 shows one example of a cross-sectional view along line I-I′ of FIG. 1 according to an embodiment of the present specification.

Although the substrate 110 is illustrated instead of the display panel 100 in FIG. 3 for convenience of description, the circuit device layer 122, the light-emitting device layer 124, and the encapsulation layer 126 that are provided on one surface of the substrate 110 are not excluded. Hereinafter, a glass substrate 110 refers to the substrate 110 on which the circuit device layer 122, the light-emitting device layer 124, and the encapsulation layer 126 are provided.

As shown in FIG. 3, an organic film 150 having a plurality of etching patterns 153a and 153b may be disposed in an etching area EA on the other surface of the substrate 110. Here, first and second etching patterns 153a and 153b may each include one or more etching patterns. However, the present specification is not limited thereto.

Moreover, in the organic film 150, a first etching hole 155a and a second etching hole 155b may be formed between an etching surface 150a and the first etching pattern 153a and between the first etching pattern 153a and the second etching pattern 153b, respectively.

Specifically, the first etching hole 155a may be formed between the first etching pattern 153a and the etching surface 150a that is on a portion of the organic film 150 located in a display panel area DPA, and the second etching hole 155b may be formed between the first etching pattern 153a and the second etching pattern 153b. A width of the first etching hole 155a may be a separation distance between the etching surface 150a and the first etching pattern 153a of the organic film 150, and a width of the second etching hole 155b may be a separation distance between the first etching pattern 153a and the second etching pattern 153b.

More specifically, a width may be formed to gradually increase from the first etching hole 155a toward the second etching hole 155b. For example, the second etching hole 155b may have a greater width than the first etching hole 155a. However, the present specification is not necessarily limited thereto.

For example, a ratio of the width of the first etching hole 155a to the width of the second etching hole 155b may range from about 1:3 to 3:5. However, the present specification is not necessarily limited thereto. More specifically, the width of the first etching hole 155a may range from about 1 μm to 3 μm (more specifically, 2 μm), and the width of the second etching hole 155b may range from about 3 μm to 10 μm, for example, from about 5 μm to 8 μm, or from about 6 μm to 7 μm. However, the present specification is not necessarily limited thereto.

Such a difference in width between the first etching hole 155a and the second etching hole 155b may be used for adjusting an etching cross-sectional shape of the etching surface of the glass substrate 110 by varying the inflow amount, the inflow speed, and the like of an etchant penetrating the substrate 110.

In addition, a polarizer film 120 and an adhesive layer 130 may be provided between the substate 110 and the cover substrate 200.

The polarizer film 120 is disposed on the substrate 110 to overlap the substrate 110.

More specifically, the polarizer film 120 may be disposed to overlap the display area of the substrate 110 to prevent or reduce a decrease in visibility due to reflection of external light. The polarizer film 120 may have a larger area than the substrate 110 and may have an end protruding past the substrate 110. For example, the substrate 110 may be formed within an area where the polarizer film 120 is formed. In the display device 10 according to one embodiment of the present disclosure, since the end of the polarizer film 120 can be disposed at the outermost possible boundary, it is advantageous in terms of securing a viewing angle.

The adhesive layer 130 is disposed on the polarizer film 120 to overlap the polarizer film 120. The adhesive layer 130 may be provided between the polarizer film 120 and the cover substrate 200 to adhere the polarizer film 120 and the cover substrate 200 to each other.

The adhesive layer 130 may have the same area as the polarizer film 120 and may have an end disposed at the same position as the polarizer film 120. Specifically, the adhesive layer 130 may be formed on the polarizer film 120 and then may be simultaneously cut with the polarizer film 120 using a laser. Accordingly, the adhesive layer 130 may have an end formed at the same position as the polarizer film 120.

In addition, since the adhesive layer 130 has the same area as the polarizer film 120, the adhesive layer 130 may have a larger area than the substrate 110. Thus, the adhesive layer 130 may have an end protruding past the substrate 110.

Since the polarizer film 120 and the adhesive layer 130 have ends that protrude past an end of the substrate 110, there may be a step difference from the substrate 110. In the display device 10 according to one embodiment of the present disclosure, a side coating film 170 may be provided to fill in the step difference between the substrate 110 and the polarizer film 120.

Specifically, the side coating film 170 may be provided at an etching surface 113 of the substrate 110 to fill in the step difference between the substrate 110 and the polarizer film 120. Here, the side coating film 170 may come into contact with a lower surface of the polarizer film 120 that is exposed due to the polarizer film 120 protruding from the end of the substrate 110. The side coating film 170 may be simultaneously cut with the polarizer film 120 using the laser, and thus, an end of the side coating film 170 may be formed at the same position as an end of the polarizer film 120.

Moreover, the side coating film 170 may be formed to cover the etching surface 113 of the substrate 110. In this way, the side coating film 170 may improve the stiffness of the etching surface of the substrate 110 that is etched.

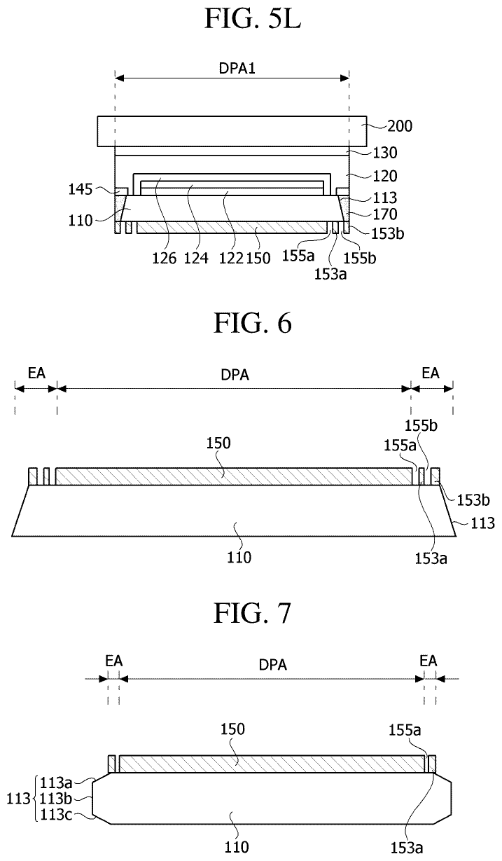

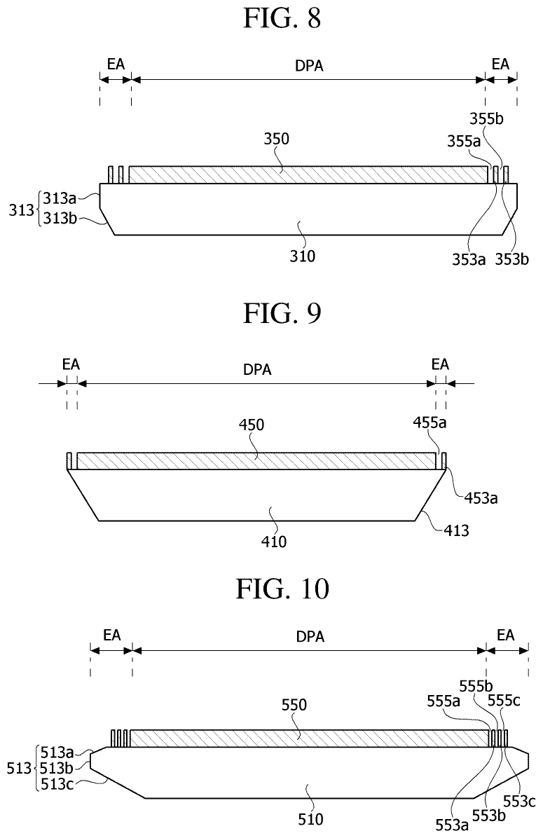

The etching surface 113 of the substrate 110 may have an inclined cross-sectional structure of various shapes as illustrated in FIGS. 6 to 10 according to a fabrication process using etching patterns of an organic film according to multiple embodiments. For example, an etching surface 113 may include a tapered side as shown in FIG. 6. An etching surface 113 may include a tapered side 113a, a vertical side 113b, and a reverse-tapered side 113c as shown in FIG. 7, an etching surface 313 may include a vertical side 313a and a reverse-tapered side 313b as shown in FIG. 8, or an etching surface 413 may include a sharply reverse-tapered side as shown in FIG. 9. In addition, an etching surface 513 may include a gently tapered side 513a, a vertical side 513b, and a very sharply reverse-tapered side 513c as shown in FIG. 10. However, the shape of the etching surface of the substrate is not limited thereto.

Display cells of a display panel may be separated from each other through a separation process and may each serve as the display panel 100. Here, a mother board of each of the plurality of display cells separated from each other may correspond to the substrate 110.

In one embodiment, the plurality of display cells may be separated from each other through a wet etching process using hydrofluoric acid. The substrate 110 of the display panel 100 may have an inclined surface where an etching surface etched by wet etching is inclined and may have a sharp end. In this case, when impact is applied to the etching surface of the substrate 110, the end of the substrate 110 may easily be damaged.

In the display device 10 according to one embodiment of the present specification, as the side coating film 170 is formed to cover the inclined etching surface 113 of the substrate 110, the sharp end of the substrate 110 may be covered by the side coating film 170. Accordingly, since the side coating film 170 serves to mitigate impact when impact is applied to the etching surface 113 of the substrate 110, the stiffness of the etching surface 113 of the substrate 110 may be improved.

In addition, the side coating film 170 may be made of an organic material that absorbs light. In one embodiment, the side coating film 170 may be made of an organic material whose optical density (OD) is about 1.0 or higher. However, the present specification is not necessarily limited thereto.

In the display device 10 according to one embodiment of the present specification, an occurrence of light leakage in the display area of the display panel 100 can be prevented or reduced by the side coating film 170, which is made of a material that absorbs light, being disposed at the etching surface 113 of the substrate 110. Accordingly, in the display device 10 according to one embodiment of the present disclosure, it is also possible to prevent or obviate the end of the substrate 110 from being visible.

In the display device 10 according to one embodiment of the present specification, since the side coating film 170 can fill in the step difference between the substrate 110 and the polarizer film 120 at the etching surface 113 of the substrate 110, the inclined shape of the etching surface 113 of the substrate 110 may be formed in various ways.

As illustrated in FIG. 3 and FIGS. 7 to 10 which will be described below, the substrate 110 may have a width formed to gradually increase from a lower portion to an upward portion of the substrate 110 where the organic film 150 is disposed, and the etching surface 113 of the substrate 110 may have a reverse-tapered shape. However, the present specification is not necessarily limited thereto.

Moreover, in another embodiment, as shown in FIG. 6, the substrate 110 may have a width formed to gradually decrease from the lower portion to the upper portion of the substrate 110, and the etching surface 113 may have a tapered shape. In still another embodiment, as shown in FIG. 7 which will be described below, the etching surface 113 of the substrate 110 may have a forward-tapered upper side, a reverse-tapered lower side, and a central portion therebetween formed to be vertical and thus be configured in a rounded shape.

In this way, in the display device according to one embodiment of the present specification, even when the shape of the etching surface 113 of the substrate 110 is formed in various ways, the etching surface 113 may be covered by the side coating film 170, and thus the degree of freedom of design with respect to the shape of the etching surface 113 of the substrate 110 may increase.

In the display device 10 according to one embodiment of the present specification, the organic film 150 may be provided on the other surface of the substrate 110. The organic film 150 may be provided to cover the entire other surface of the substrate 110 from below the substrate 110.

The organic film 150 may include a first cover part (not illustrated) configured to cover a central area of the substrate 110 and a second cover part (not illustrated) configured to cover the etching area EA located on an outer boundary portion of the central area of the substrate 110. The organic film 150 may not only serve to allow etching of the etching area EA of the substrate 110 but also serve to protect the substrate 110. In addition, the organic film 150 may be formed of an organic material and serve to mitigate impact to prevent or reduce an external impact from being transmitted to the display panel 100.

In the display device according to one embodiment of the present specification, an etching prevention film 145 may be provided between the side coating film 170 and the polarizer film 120. The etching prevention film 145 may determine an etching depth when cutting the substrate 110 through a wet etching process.

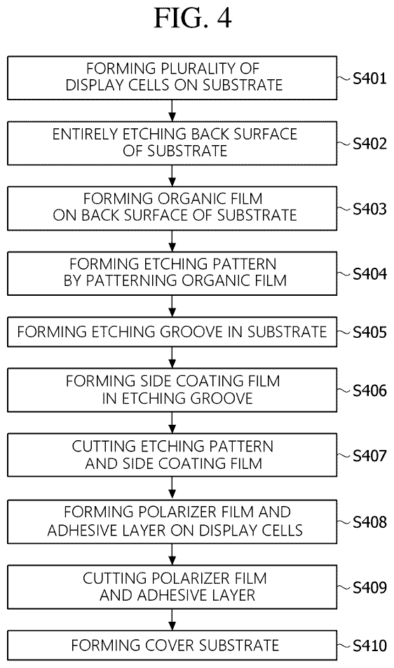

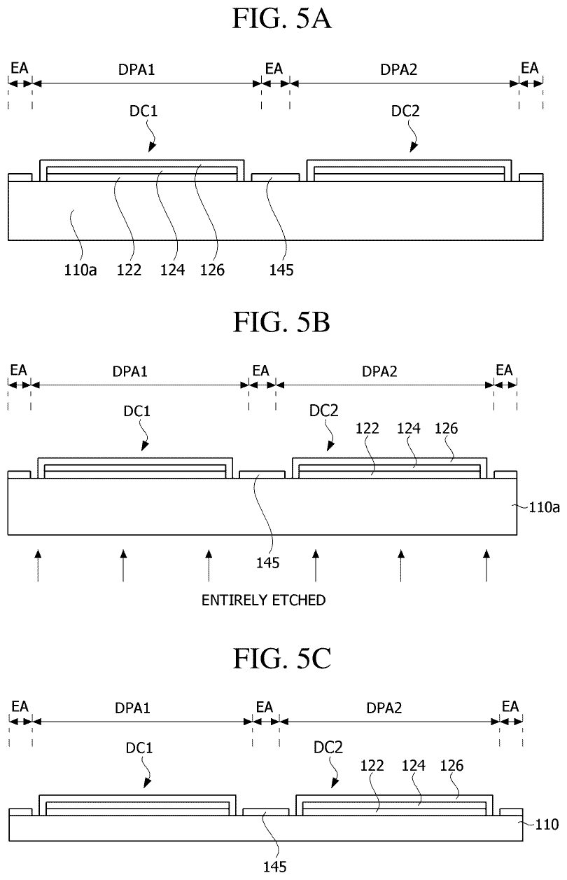

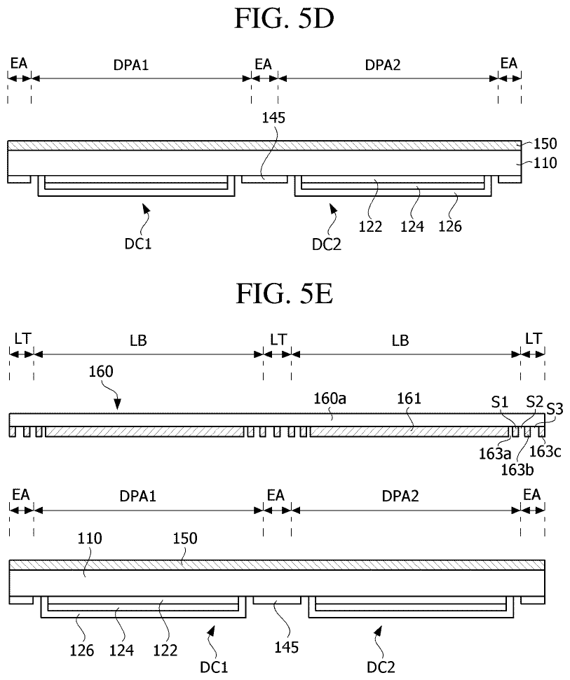

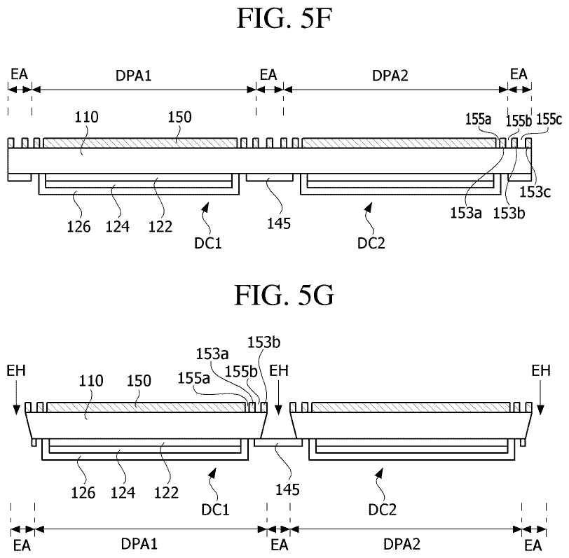

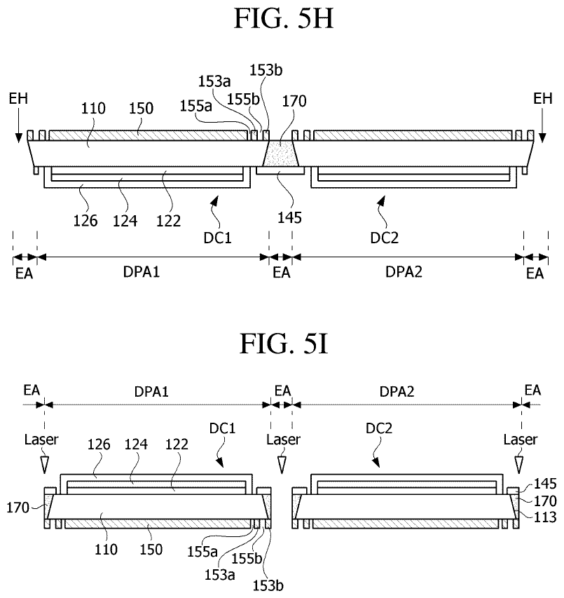

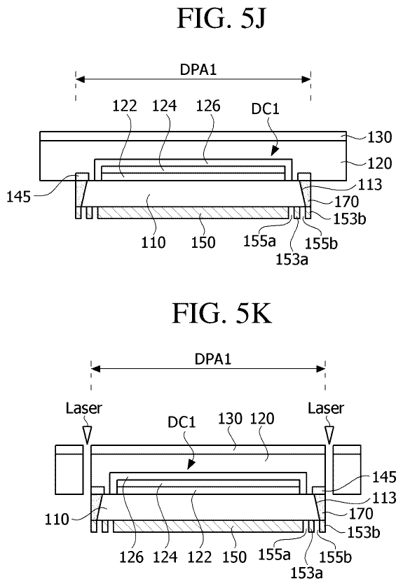

In addition, a process of etching the glass substrate 110 through a wet etching process will be described in more detail with reference to FIGS. 4 and 5.

FIG. 4 is a flowchart showing a method of fabricating a display device according to one embodiment of the present specification, and FIGS. 5A to 5L are cross-sectional views showing the method of fabricating the display device according to the one embodiment of the present specification.

First, as a first operation (S401), a plurality of display cells DC are formed on the substrate 110.

More specifically, referring to FIG. 5A, display cells DC1 and DC2 may be formed in a plurality of display panel areas DPA1 and DPA2, respectively, on a substrate 110a. Here, the substrate 110a may be a mother board.

First, the circuit device layer 122 may be formed on the substrate 110a. A circuit device including various signal lines, a thin film transistor, a capacitor, and the like may be provided for each pixel in the circuit device layer 122. The signal lines may include a scan line, a data line, a driving power line, a common power line, and a reference line, and the thin film transistor may include a switching thin film transistor, a driving thin film transistor, and a sensing thin film transistor, but the present disclosure is not limited thereto.

Then, the light-emitting device layer 124 may be formed on the circuit device layer 122. The light-emitting device layer 124 includes a plurality of light-emitting devices. The plurality of light-emitting devices may each include first electrodes, a light-emitting layer, and a second electrode.

The light-emitting layer may be an organic light-emitting layer including an organic material. In this case, the light-emitting layer may include a hole transporting layer, an organic light-emitting layer, and an electron transporting layer.

When a voltage is applied to the first electrodes and the second electrodes, holes and electrons move to the organic light-emitting layer through the hole transporting layer and the electron transporting layer, respectively, and combine with each other, thereby emitting light.

The light-emitting device layer 124 may be a pixel array layer on which pixels are formed, and thus an area in which the light-emitting device layer 124 is formed may be defined as a display area. In addition, an area around the display area may be defined as a non-display area.

Next, the encapsulation layer 126 may be formed on the light-emitting device layer 124. The encapsulation layer 126 serves to prevent or reduce penetration of oxygen or moisture into the light-emitting device layer 124. The encapsulation layer 126 may include at least one inorganic film and at least one organic film.

In addition, an etching prevention film 145 may be formed along the etching area EA on one surface of the substrate 110a. Here, the etching area EA may be an area partitioning the plurality of display panel areas DPA1 and DPA2. Accordingly, the etching area EA may be provided between the plurality of display panel areas DPA1 and DPA2. The etching prevention film 145 may be formed of the same material as at least one of a plurality of insulation films (not illustrated) provided on the circuit device layer 122, the light-emitting device layer 124, and the encapsulation layer 126. For example, a planarization film for planarizing a step difference between a driving transistor and a light-emitting device that occurs due to the driving transistor may be provided at the circuit device layer 122. The etching prevention film 145 may be simultaneously formed with and made of the same material as the planarization film provided on the circuit device layer 122.

Next, as a second operation (S402), the other surface (e.g., the back surface) of the substrate 110a is entirely etched. More specifically, referring to FIGS. 5B and 5C, the other surface of the substrate 110a may be entirely etched to form the substrate 110 having a predetermined thickness. For example, the substrate 110a may be etched so that the substrate 110 has a thickness of about 0.2 t, where t represents the original thickness of the substrate 110a. However, the present specification is not limited thereto.

Then, as a third operation (S403), in a state in which the substrate 110 is flipped upside down, e.g., the other surface thereof is located upward, the organic film 150 is formed on the other surface of the substrate 110 that is entirely etched.

More specifically, referring to FIG. 5D, an organic material may be applied on the entire other surface of the substrate 110 to form the organic film 150. The organic material forming the organic film 150 may be a colorless, transparent material, but the present specification is not necessarily limited thereto. The material forming the organic film 150 may also be a colored organic material. The material forming the organic film may be applied on the other surface of the substrate 110 using a screen printer, but the present specification is not necessarily limited thereto.

Next, as a fourth operation (S404), referring to FIG. 5E, the exposure mask 160 may be disposed on the upper side of the organic film 150 of the substrate 110 at a predetermined interval. Here, the exposure mask 160 may include a light blocking part LB and a light transmitting part LT.

The light blocking part LB of the exposure mask 160 may be located to overlap the plurality of display panel areas DPA1 and DPA2, and the light transmitting part LT may be located to overlap the etching area EA between the plurality of display panel areas DPA1 and DPA2. Here, a portion of the light transmitting part LT may overlap a portion of each of the plurality of display panel areas DPA1 and DPA2. However, the present specification is not limited thereto.

The exposure mask 160 may include a transparent substrate 160a, a first light blocking pattern 161, and second-first to second-third light blocking patterns 163a, 163b, and 163c including a plurality of slits S1, S2, and S3.

The first light blocking pattern 161 may be provided on the light blocking part LB of the exposure mask 160, and the second-first, second-second, and second-third light blocking patterns 163a, 163b, and 163c may be provided on the light transmitting part LT. Here, first to third slits S1, S2, and S3 may be formed between the second-first, second-second, and second-third light blocking patterns 163a, 163b, and 163c. Here, the first to third slits S1, S2, and S3 may adjust the intensity of a transmissive light source to adjust line widths of the second-first, second-second, and second-third light blocking patterns 163a, 163b, and 163c. In addition, the second-first, second-second, and second-third light blocking patterns 163a, 163b, and 163c may each include one or more light blocking patterns, but the present specification is not limited thereto.

The first slit S1 may be formed between the first light blocking pattern 161 and the second-first light blocking pattern 163a, and the second slit S2 may be formed between the second-first light blocking pattern 163a and the second-second light blocking pattern 163b. In addition, the third slit S3 may be formed between the second-second light blocking pattern 163b and the second-third light blocking pattern 163c.

Here, a width may be formed to gradually increase from the first slit S1 toward the third slit S3. More specifically, the second slit S2 may have a greater width than the first slit S1, and the third slit S3 may have a greater width than the second slit S2. However, the present specification is not limited thereto.

For example, a ratio of the width of the first slit S1 to the width of the second slit S2 to the width of the third slit S3 may be defined as ranging from about 1:3:5 to 1:5:10. However, the present specification is not necessarily limited thereto. Specifically, the width of the first slit S1 may range from about 1 to 3 μm, the width of the second slit S2 may range from about 3 to 10 μm, and the width of the third slit S3 may range from 5 to 50 μm. However, the present specification is not necessarily limited thereto.

Next, an exposure process of irradiating the organic film 150 with light is performed using a photolithography technique via the exposure mask 160. Here, during the exposure process, while light is blocked by the light blocking part LB provided at the exposure mask 160, light is transmitted through the light transmitting part LT, and the organic film 150 may be irradiated with the light.

In particular, the organic film 150 may be irradiated with the light through the first to third slits S1, S2, and S3 between the second-first to second-third light blocking patterns 163a, 163b, and 163c constituting the light transmitting part LT. Here, an area irradiated with the light may be the etching area EA of the organic film 150.

Then, referring to FIG. 5F, by developing and removing the exposed portion of the organic film 150 that corresponds to the etching area EA, first to third etching patterns 153a, 153b, and 153c may be formed in the etching area EA of the organic film 150. Here, the first to third etching patterns 153a, 153b, and 153c may be formed at positions overlapping the second-first to second-third light blocking patterns 163a, 163b, and 163c of the exposure mask 160. The first to third etching patterns 153a, 153b, and 153c may each include one or more etching patterns. However, the present specification is not limited thereto.

In addition, first to third etching holes 155a, 155b, and 155c may be formed between the first to third etching patterns 153a, 153b, and 153c.

The first etching hole 155a may be formed between the first etching pattern 153a and the etching surface 150a (shown in FIG. 3) that is on a portion of the organic film 150 located in the display panel areas DPA1 and DPA2, and the second etching hole 155b may be formed between the first etching pattern 153a and the second etching pattern 153b. Moreover, the third etching hole 155c may be formed between the second etching pattern 153b and the third etching pattern 153c.

More specifically, a width may be formed to gradually increase from the first etching hole 155a toward the third etching hole 155c. More specifically, the second etching hole 155b may have a greater width than the first etching hole 155a, and the third etching hole 155c may have a greater width than the second etching hole 155b. However, the present specification is not limited thereto.

For example, a ratio of the diameter of the first etching hole 155a to the diameter of the second etching hole 155b to the diameter of the third etching hole 155c may be defined as ranging from about 1:3:5 to 1:5:10. However, the present specification is not necessarily limited thereto. Specifically, the diameter of the first etching hole 155a may range from about 1 to 3 μm, the diameter of the second etching hole 155b may range from about 3 to 10 μm, and the diameter of the third etching hole 155c may range from 5 to 50 μm. However, the present specification is not necessarily limited thereto.

Next, as a fifth operation (S405), an etching groove EH is formed by performing wet etching using an etchant on a portion of the substrate 110 located on the etching area EA by using the organic film 150, having the first to third etching patterns 153a, 153b, and 153c, as an etching mask. Here, the third etching pattern 153c may be removed in the process of forming the etching groove EH. However, the present specification is not limited thereto.

More specifically, referring to FIGS. 5F and 5G, the etching groove EH may be formed due to the substrate 110 being isotropically etched as an etchant (not illustrated) penetrates into a surface of the substrate 110 along the first to third etching holes 155a, 155b, and 155c between the first to third etching patterns 153a, 153b, and 153c through a wet etching process using hydrofluoric acid.

Here, since the degree to which the etchant penetrates into the substrate 110 is different along each of the first to third etching holes 155a, 155b, and 155c, the degree to which the etching surface of the substrate 110 is etched may vary also according to the thickness of the substrate 110.

For example, referring to the embodiments of FIGS. 6 to 10 that will be described below, the etching surface 113 of the substrate 110 located in the etching area EA may include a forward-tapered cross-section as shown in FIG. 6, may include a forward-tapered cross-section, a vertical side, and a reverse-tapered cross-section as shown in FIG. 7, may include a vertical side and a reverse-tapered cross-section as shown in FIG. 8, may include a steep reverse-tapered cross-section as shown in FIG. 9, or may include a gentle forward-tapered cross-section, a vertical side, and a steep reverse-tapered cross-section as shown in FIG. 10. However, the etching surface 113 of the substrate 110 may have an etching cross-sectional structure of various shapes other than those described above depending on the shapes of the etching patterns of the organic film 150.

Moreover, referring to FIG. 5F, the shape of the etching surface 113 of the substrate 110 may vary according to the sizes, e.g., widths or diameters, of the first to third etching holes 155a, 155b, and 155c between the first to third etching patterns 153a, 153b, and 153c or according to the inflow amount, the inflow speed, and the like of an etchant introduced into the substrate 110 through the first to third etching holes 155a, 155b, and 155c. However, the present specification is not limited thereto.

Further, although the etching groove EH may be formed through one wet etching process, the present specification is not necessarily limited thereto. In another embodiment, the etching groove EH may be formed through multiple wet etching processes along the thickness of the substrate 110. For example, a portion of the thickness of the substrate 110 may be etched along the etching area EA through a first wet etching process. Then, the rest of the thickness of the substrate 110 may be etched along the etching area EA through a second wet etching process.

Specifically, referring to FIG. 6 illustrating a first embodiment, the etching surface 113 of the etching area EA of the substrate 110 may include a cross-sectional structure having a forward-tapered shape.

Moreover, referring to FIG. 7 illustrating a second embodiment, the etching surface 113 may include a cross-sectional structure having a forward-tapered side 113a, a vertical side 113b, and a reverse-tapered side 113c.

In addition, referring to FIG. 8 illustrating a third embodiment, an etching surface 313 of an etching area EA of a substrate 310 may include a cross-sectional structure having a vertical side 313a and a gently reverse-tapered side 313b. Further, referring to FIG. 9 illustrating a fourth embodiment, an etching surface 413 of an etching area EA of a substrate 410 may include an inclined cross-sectional structure having a steep reverse-tapered shape. In addition, referring to FIG. 10 illustrating a fifth embodiment, an etching surface 513 of an etching area EA of a substrate 510 may include a cross-sectional structure having a gently forward-tapered side 513a, a vertical side 513b, and a steep reverse-tapered side 513c.

Then, as a sixth operation (S406), the side coating film 170 is formed in the etching groove EH of the substrate 110.

More specifically, referring to FIG. 5H, in a state in which the etching groove EH of the substrate 110 faces upward, an organic material may be applied on the etching groove EH to form the side coating film 170. The side coating film 170 may be made of a colored organic material that absorbs light. In one embodiment, the side coating film 170 may be made of an organic material whose optical density (OD) is about 1.0 or higher. The organic material may be applied on the etching groove EH using an ink dispenser. The material forming the side coating film 170 may be the same as the material forming the organic film 150. However, the present specification is not necessarily limited thereto. The side coating film 170 may be applied on the etching groove EH using any of various known methods.

Next, as a seventh operation (S407), the side coating film 170 and the organic film 150 (e.g., etching pattern) are cut.

More specifically, referring to FIG. 5I, the side coating film 170 disposed at the etching groove EH and the organic film 150 disposed on the other surface of the substrate 110 may be cut along a first cutting line. Here, the first cutting line may be a line for cutting the side coating film 170 and the organic film 150 and may be collinear with the etching area EA and allow cutting of the side coating film 170 disposed at the etching groove EH.

Here, the organic film 150 cut along the first cutting line may be at least one of the first and second etching patterns 153a and 153b located in the etching area EA.

The substrate 110 is not provided along the first cutting line because the substrate 110 is etched by the wet etching process. Accordingly, the etching prevention film 145, the side coating film 170, and the first and second etching patterns 153a and 153b may be disposed along the first cutting line.

Since the etching prevention film 145, the side coating film 170, and the first and second etching patterns 153a and 153b are all formed of an organic material, all of them may be simultaneously cut using a laser. Accordingly, a step difference may not occur between the etching prevention film 145, the side coating film 170, and the first and second etching patterns 153a and 153b, and ends thereof may be formed at the same position.

When the side coating film 170 and one of the first and second etching patterns 153a and 153b are cut, a plurality of display panels each having a plurality of display cells DC1 and DC2 formed thereon may be separated from each other.

Next, as an eighth operation (S408), the polarizer film 120 and the adhesive layer 130 are sequentially formed on the display cells DC1 and DC2. However, the present specification is not limited thereto.

More specifically, referring to FIG. 5J, the polarizer film 120 and the adhesive layer 130 may constitute an adhesive film. In addition, an end of the adhesive film may be formed to protrude past an end of the side coating film 170.

Then, as a ninth operation (S409), the adhesive film including the polarizer film 120 and the adhesive layer 130 is cut.

More specifically, referring to FIG. 5K, the polarizer film 120 and the adhesive layer 130 may be cut along a second cutting line. Here, the second cutting line may be a line for cutting the polarizer film 120 and the adhesive layer 130 and may be collinear with the etching area, but the present specification is not necessarily limited thereto. The second cutting line may also be disposed inside of the etching area. Even in this case, the second cutting line may not overlap the substrate 110. In addition, the second cutting line may be disposed outside of the etching area.

When the second cutting line is collinear with the etching area or is disposed inside of the etching area, since the adhesive film including the polarizer film 120 and the adhesive layer 130, the etching prevention film 145, the side coating film 170, and the organic film 150 are all formed of an organic material, all of them may simultaneously be cut using a laser as shown in FIG. 5K. Accordingly, a step difference may not occur between the adhesive film including the polarizer film 120 and the adhesive layer 130, the etching prevention film 145, the side coating film 170, and the organic film 150, and ends thereof may be formed at the same position.

In addition, when the second cutting line is disposed outside of the etching area, the adhesive film including the polarizer film 120 and the adhesive layer 130 may be simultaneously cut using a laser. A step difference may not occur in the adhesive film including the polarizer film 120 and the adhesive layer 130 and ends thereof may be formed at the same position. However, the adhesive film including the polarizer film 120 and the adhesive layer 130 may be formed at a position where ends thereof protrude past the etching prevention film 145, the side coating film 170, and the first and second etching patterns 153a and 153b of the organic film 150.

Then, as a tenth operation (S410), the cover substrate 200 is formed on the adhesive layer 130.

More specifically, referring to FIG. 5L, a base layer of the adhesive film may be removed, and the cover substrate 200 may be adhered onto the adhesive layer 130.

In addition, embodiments of etching cross-sectional structures of a glass substrate according to a display device of the present specification will be described with reference to FIGS. 6 to 10.

FIG. 6 is a cross-sectional view showing a substrate etching form of a display panel according to a first embodiment of the present specification. FIG. 7 is a cross-sectional view showing a substrate etching form of a display panel according to a second embodiment of the present specification. FIG. 8 is a cross-sectional view showing a substrate etching form of a display panel according to a third embodiment of the present specification. FIG. 9 is a cross-sectional view showing a substrate etching form of a display panel according to a fourth embodiment of the present specification, and FIG. 10 is a cross-sectional view showing a substrate etching form of a display panel according to a fifth embodiment of the present specification.

In FIG. 6, for convenience of description, a substrate 110 is illustrated instead of a display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2) that are provided on the substrate 110 are not excluded.

Hereinafter, the substrate 110 may refer to a glass substrate on which the circuit device layer 122, the light-emitting device layer 124, and the encapsulation layer 126 are provided.

Referring to FIG. 6, a display device according to the first embodiment of the present specification may include the organic film 150 disposed on the other surface of the glass substrate 110 and having the first and second etching patterns 153a and 153b corresponding to the etching area EA.

Here, the first and second etching patterns 153a and 153b may each include one or more etching patterns. However, the present specification is not limited thereto.

In addition, the first and second etching holes 155a and 155b may be formed between the first and second etching patterns 153a and 153b.

The first etching hole 155a may be formed between the first etching pattern 153a and a portion of the organic film 150 that is located in a display panel area DPA, and the second etching hole 155b may be formed between the first etching pattern 153a and the second etching pattern 153b.

More specifically, the second etching hole 155b may have a greater width than the first etching hole 155a. However, the present specification is not necessarily limited thereto.

For example, a ratio of the width of the first etching hole 155a to the width of the second etching hole 155b may range from at least 1:3 to 1:5. However, the present specification is not necessarily limited thereto.

More specifically, the size of the width of the first etching hole 155a may range from about 1 μm to 3 μm, and the size of the width of the second etching hole 155b may range from about 3 μm to 15 μm. However, the widths of the etching holes are not necessarily limited thereto.

Such a difference in width between the first etching hole 155a and the second etching hole 155b is for adjusting an etching cross-sectional shape of an etching surface of the substrate 110 by varying the inflow amount, the inflow speed, and the like of an etchant penetrating the substrate 110.

Accordingly, since the first etching hole 155a and the second etching hole 155b are configured to have widths of different sizes, the degree to which the etching surface 113 located in the etching area EA of the substrate 110 is etched may be different at an upper portion and a lower portion.

Specifically, the amount of etchant penetrating the substrate 110 through the second etching hole 155b may be greater than the amount of etchant penetrating the substrate 110 through the first etching hole 155a having a smaller width.

Accordingly, since the speed of isotropic etching gradually decreases from the upper portion toward the lower portion in relation to the degree to which the etching surface 113 of the substrate 110 is etched, a cross-section having a forward-tapered shape may be formed.

In FIG. 7, for convenience of description, a substrate 110 is illustrated instead of the display panel 100, but a circuit device layer (not illustrated) (see 122 of FIG. 2), a light-emitting device layer (not illustrated) (see 124 of FIG. 2), and an encapsulation layer (not illustrated) (see 126 of FIG. 2) that are provided on one surface of the substrate 110 are not excluded.

Hereinafter, the substrate 110 may refer to a glass substrate on which the circuit device layer 122, the light-emitting device layer 124, and the encapsulation layer 126 are provided.

Referring to FIG. 7, a display device according to the second embodiment of the present specification includes the organic film 150 disposed on the other surface of the substrate 110 and having a plurality of first etching patterns 153a provided in the etching area EA.

Here, the first etching patterns 153a may each include one or more etching patterns. However, the present specification is not limited thereto.

In addition, the first etching hole 155a may be formed between the first etching patterns 153a.

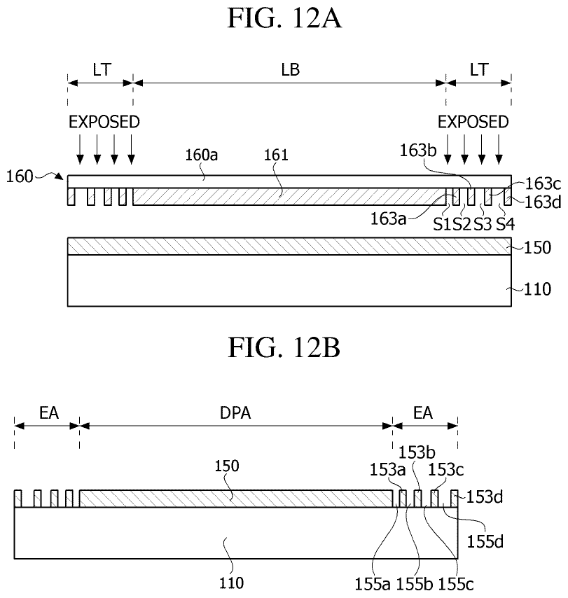

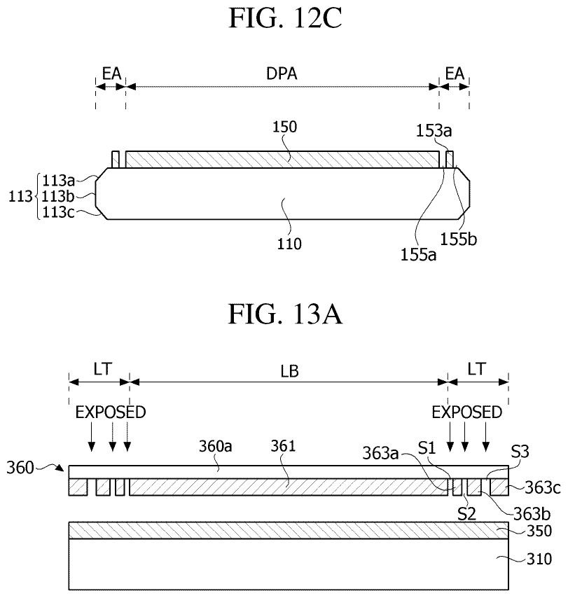

The first etching hole 155a may be formed between the first etching pattern 153a and an etching surface that is on a portion of the organic film 150 located in the display panel area DPA. More specifically, when the plurality of first etching patterns 153a are provided, the width of an etching hole may be formed to gradually increase from the first etching hole 155a toward etching holes 155b, 155c, and 155d (see FIG. 12B) between outer boundary-side etching patterns 153b, 153c, and 153d (see FIG. 12B). However, the present specification is not necessarily limited thereto.

Such a difference in width between the first etching hole 155a and the etching holes 155b, 155c, and 155d (see FIG. 12B) at an outer boundary thereof is for adjusting an etching cross-sectional shape of an etching surface of the substrate 110 by varying the inflow amount, the inflow speed, and the like of an etchant penetrating the substrate 110.

In FIG. 7, since etching of an etching surface in the etching area EA of the substrate 110 is isotropically performed as the amount of etchant introduced into the substrate 110 gradually increases through the first etching hole 155a of the organic film 150 and the etching holes 155b, 155c, and 155d (see FIG. 12B) at the outer boundary thereof, the etching surface 113 of the substrate 110 in the etching area EA may have a cross-section having a rounded shape. For example, the etching surface 113 of the substrate 110 that is located below the first etching hole 155a and the second etching hole 155b (see FIG. 12B) may include a forward-tapered side 113a and a reverse-tapered side 113c and include a vertical side 113b disposed therebetween. More specifically, an upper portion of the etching surface 113 may have the forward-tapered side 113a, a central portion of the etching surface 113 may have the vertical side 113b, and a lower portion of the etching surface 113 may have the reverse-tapered side 113c.

This allows a small amount of etchant to be introduced through the first and second etching holes 155a and 155b (see FIG. 12B) that have a small width and a greater amount of etchant to be introduced through the third and fourth etching holes 155c and 155d (see FIG. 12B) as compared to the first and second etching holes 155a and 155b (see FIG. 12B), and in this way, the degree to which the etching surface 113 of the substrate 110 is etched may vary.

Accordingly, the etching surface 113 of the substrate 110 may constitute a rounded cross-sectional structure having the forward-tapered side 113a, the vertical side 113b, and the reverse-tapered side 113c due to performing wet etching using an etchant. Here, since the rounded cross-sectional structure having the forward-tapered side 113a, the vertical side 113b, and the reverse-tapered side 113c is formed on the etching surface 113 of the substrate 110, among the first to fourth etching patterns 153a, 153b, 153c, and 153d, some etching patterns 153b, 153c, and 153d may be removed and no longer remain. For example, the second to fourth etching patterns 153b, 153c, and 153d may be removed due to a portion of the substrate 110 located there below being etched by wet etching. However, the present specification is not necessarily limited thereto.

Moreover, in FIG. 8, for convenience of description, a glass substrate 310 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on the substrate 310, are not excluded.

Hereinafter, the substrate 310 may refer to a glass substrate on which the circuit device layer 122, the light-emitting device layer 124, and the encapsulation layer 126 are provided.

Referring to FIG. 8, a display device according to the third embodiment of the present specification may include an organic film 350 disposed on the other surface of the substrate 310 and having a plurality of first, second, and third etching patterns 353a, 353b, and 353c corresponding to the etching area EA.

Here, the first and second etching patterns 353a and 353b may each include one or more etching patterns. However, the present specification is not limited thereto.

Moreover, first and second etching holes 355a and 355b may be formed between the first and second etching patterns 353a and 353b.

The first etching hole 355a may be formed between the first etching pattern 353a and a portion of the organic film 350 that is located in a display panel area DPA, and the second etching hole 355b may be formed between the first etching pattern 353a and the second etching pattern 353b.

More specifically, the first etching hole 355a and the second etching hole 355b may have widths of similar sizes. However, the present specification is not necessarily limited thereto.

For example, a ratio of the width of the first etching hole 355a to the width of the second etching hole 355b may range from about 1:1 to 1:2. However, the present specification is not necessarily limited thereto.

More specifically, the size of the width of the first etching hole 355a may range from about 1 μm to 5 μm, and the size of the width of the second etching hole 355b may range from about 1 μm to 10 μm. However, the widths of the etching holes are not necessarily limited thereto.

Such a difference in width between the first etching hole 355a and the second etching hole 355b is for adjusting an etching cross-sectional shape of an etching surface of the substrate 310 by varying the inflow amount, the inflow speed, and the like of an etchant penetrating the substrate 310.

Here, since the first etching hole 355a and the second etching hole 355b are configured to have widths of similar sizes, the degree to which the etching surface 313 located in the etching area EA of the substrate 310 is etched may only be slightly different on an upper portion and a lower portion thereof.

Specifically, since the amount of etchant penetrating the substrate 310 through the first etching hole 355a and the second etching hole 355b that have a small width is small, and the speed thereof is slow, a vertical side 313a may be formed on the upper portion of the etching surface 313 of the substrate 310, and a slightly reverse-tapered side 313b may be formed on the lower portion of the etching surface 313 of the substrate 310.

Accordingly, since an etchant is introduced in similar amounts through the first and second etching holes 355a and 355b, a cross-section having the vertical side 313a and the reverse-tapered side 313b may be formed due to the etching surface 313 of the substrate 310 being etched by wet etching using the etchant introduced through the first and second etching holes 355a and 355b.

In FIG. 9, for convenience of description, a substrate 410 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on the substrate 410, are not excluded.

Hereinafter, the substrate 410 may refer to a glass substrate on which the circuit device layer 122, the light-emitting device layer 124, and the encapsulation layer 126 are provided.

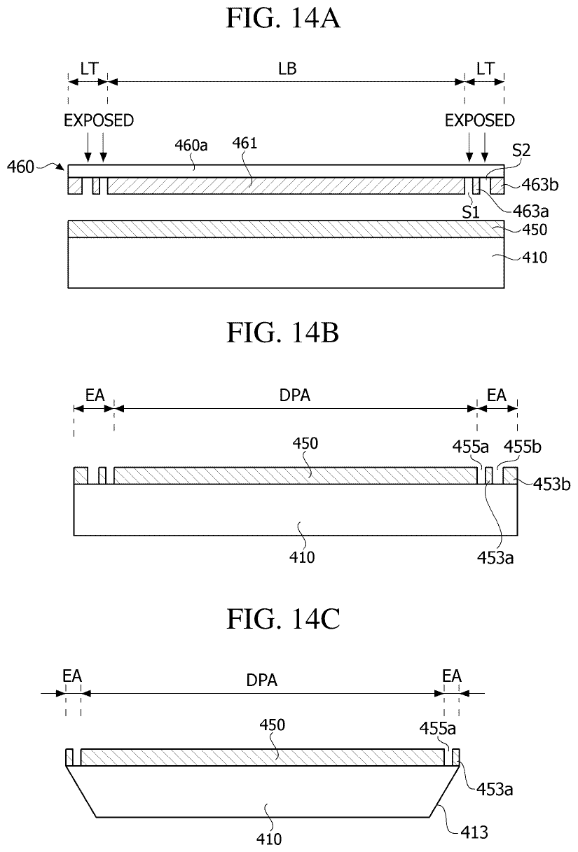

In addition, referring to FIG. 9, a display device according to the fourth embodiment of the present specification includes an organic film 450 disposed on the other surface of the substrate 410 and having first and second etching patterns 453a and 453b (see FIG. 14B) located in the etching area EA.

Here, the first and second etching patterns 453a and 453b may each include one or more etching patterns. However, the present specification is not limited thereto.

In addition, a first etching hole 455a may be formed between the organic film 450 and the first etching pattern 453a.

The first etching hole 455a may be formed between the first etching pattern 453a and a portion of the organic film 450 located in the display panel area DPA.

More specifically, a width of a second etching hole 455b (see FIG. 14B) may be formed to be greater than a width of the first etching hole 455a. For example, a ratio of the width of the first etching hole 455a to the width of the second etching hole 455b (see FIG. 14B) may be about 1:5 or more. However, the present specification is not necessarily limited thereto.

Moreover, the width of the first etching hole 455a may range from about 1 μm to 5 μm, and the width of the second etching hole 455b (see FIG. 14B) may range from about 5 μm to 30 μm. However, the widths of the etching holes are not necessarily limited thereto.

Such a difference in width between the first etching hole 455a and the second etching hole 455b (see FIG. 14B) is for adjusting an etching cross-sectional shape of an etching surface of the substrate 410 by varying the inflow amount, the inflow speed, and the like of an etchant penetrating the substrate 410.

In FIG. 9, the amount of etchant introduced into the substrate 410 through the second etching hole 455b of the organic film 450 is greater than the amount of etchant introduced through the first etching hole 455a.

As a result, since etching of an etching surface in the etching area EA of the substrate 410 is isotropically performed more rapidly through the second etching hole 455b (see FIG. 14B) than through the first etching hole 455a, an etching surface 413 of the substrate 410 in the etching area EA may include a cross-section having a steep reverse-tapered shape.

Moreover, in FIG. 10, for convenience of description, a substrate 510 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on the substrate 510, are not excluded.

Hereinafter, the substrate 510 may refer to a glass substrate on which the circuit device layer 122, the light-emitting device layer 124, and the encapsulation layer 126 are provided.

Referring to FIG. 10, a display device according to the fifth embodiment of the present specification includes an organic film 550 disposed on the other surface of the substrate 510 and having first to third etching patterns 553a, 553b, and 553c located in the etching area EA.

Here, the first to third etching patterns 553a, 553b, and 553c may each include one or more etching patterns. However, the present specification is not limited thereto.

Moreover, first to third etching holes 555a, 555b, and 555c may be formed between the first to third etching patterns 553a, 553b, and 553c.

More specifically, the first etching hole 555a may be formed between the first etching pattern 553a and a portion of the organic film 550 that is located in a display panel area DPA, and the second etching hole 555b may be formed between the first etching pattern 553a and the second etching pattern 553b. In addition, the third etching hole 555c may be formed between the second etching pattern 553b and the third etching pattern 553c.

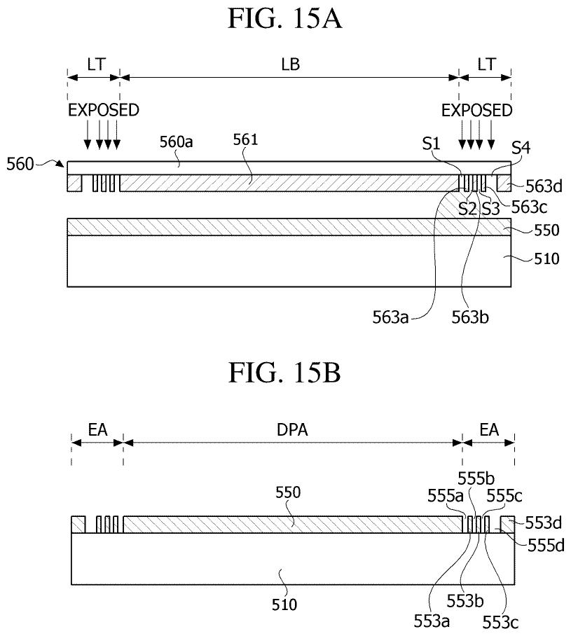

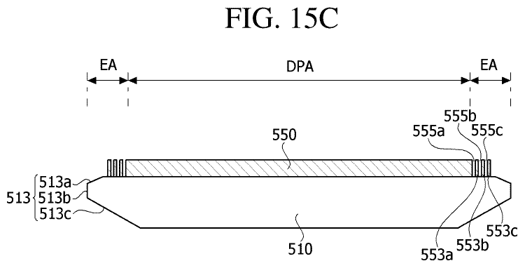

More specifically, the first to third etching holes 555a, 555b, and 555c may be formed to have widths of similar sizes, and a width of a fourth etching hole 555d (see FIG. 15B) may be formed to be greater than the widths of the first to third etching holes 555a, 555b, and 555c.

For example, a ratio of the widths of the first to third etching holes 555a, 555b, and 555c to the width of the fourth etching hole 555d (see FIG. 15B) may be about 1:3 or more. However, the present specification is not necessarily limited thereto.

Moreover, the widths of the first to third etching holes 555a, 555b, and 555c may range from about 1 μm to 5 μm, and the width of the fourth etching hole 555d (see FIG. 15B) may range from about 3 μm to 20 μm. However, the widths of the etching holes are not necessarily limited thereto.

Such a difference in width between the first to third etching holes 555a, 555b, and 555c and the fourth etching hole 555d is for adjusting an etching cross-sectional shape of an etching surface of the substrate 510 by varying the inflow amount, the inflow speed, and the like of an etchant penetrating the substrate 510.

In FIG. 10, the amount of etchant introduced into the substrate 510 through the fourth etching hole 555d of the organic film 550 is greater than the amount of etchant introduced through the first to third etching holes 555a, 555b, and 555c. As a result, since etching of an etching surface in the etching area EA of the substrate 510 is more isotropically performed through the fourth etching hole 555d (see FIG. 15B) than through the first to third etching holes 555a, 555b, and 555c, the etching surface 513 of the substrate 510 in the etching area EA may have a cross-section including a forward-tapered side 513a, a vertical side 513b, and a reverse-tapered side 513c. In addition, the reverse tapered side may be inclined at a greater angle than the forward tapered side.

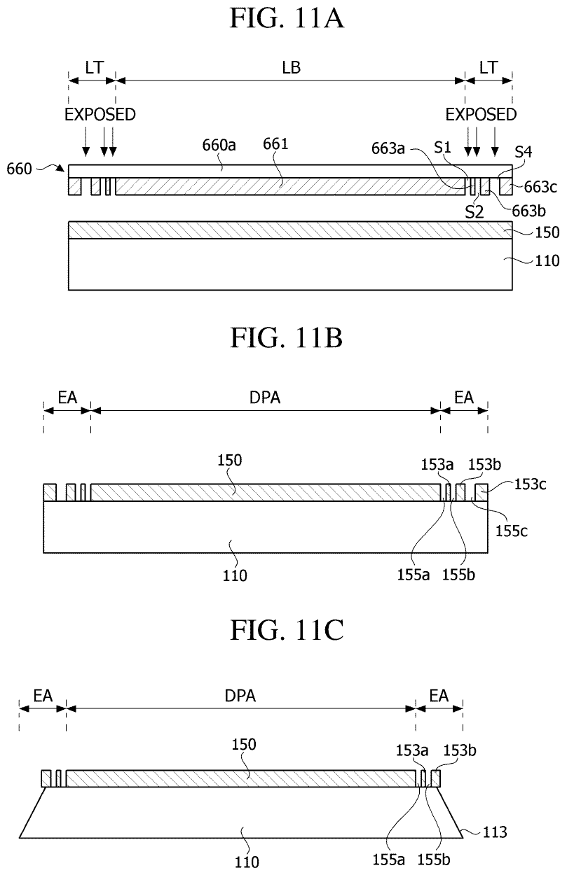

FIGS. 11A to 11C are cross-sectional views showing a process of etching a substrate of the display panel according to the first embodiment of the present specification.

In FIGS. 11A to 11C, for convenience of description, a substrate 110 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on one surface of the substrate 110, are not excluded.

Hereinafter, the substrate 110 may refer to a glass substrate on which the circuit device layer 122, the light-emitting device layer 124, and the encapsulation layer 126 are provided.

Referring to FIG. 11A, after entirely etching the other surface of the substrate 110, the organic film 150 is formed on the other surface of the substrate 110 that is located to face upward in a state in which the substrate 110 is flipped upside down.

Specifically, the organic film 150 is formed by applying an organic material on the entire other surface of the substrate 110. Here, the organic material forming the organic film 150 may be a colorless, transparent material, but the present specification is not necessarily limited thereto. In addition, the material forming the organic film may also be a colored organic material. The material forming the organic film may be applied on the other surface of the substrate 110 using a screen printer, but the present specification is not necessarily limited thereto.

Next, an exposure mask 660 is disposed on an upper side of the organic film 150 at a predetermined distance.

Here, the exposure mask 660 may include a light blocking part LB and a light transmitting part LT. The light blocking part LB of the exposure mask 660 may be located to overlap a plurality of display panel areas DPA, and the light transmitting part LT may be located to overlap etching areas EA between the plurality of display panel areas DPA. Here, a portion of the etching areas EA may overlap a portion of each of the plurality of display panel areas DPA.

The exposure mask 660 may include a transparent substrate 660a, a first light blocking pattern 661, and second-first to second-third light blocking patterns 663a, 663b, and 663c including a plurality of slits S1, S2, and S3.

Moreover, the first light blocking pattern 661 may be provided at the light blocking part LB of the exposure mask 660, and the second-first to second-third light blocking patterns 663a, 663b, and 663c may be provided at the light transmitting part LT. Here, first to third slits S1, S2, and S3 may be formed between the second-first to second-third light blocking patterns 663a, 663b, and 663c. Here, the first to third slits S1, S2, and S3 may adjust the intensity of a transmissive light source to adjust line widths of the second-first, second-second, and second-third light blocking patterns 663a, 663b, and 663c. In addition, the second-first to second-third light blocking patterns 663a, 663b, and 663c may each include one or more light blocking patterns, but the present specification is not limited thereto.

The first slit S1 may be formed between the first light blocking pattern 661 and the second-first light blocking pattern 663a, and the second slit S2 may be formed between the second-first light blocking pattern 663a and the second-second light blocking pattern 663b. Further, the third slit S3 may be formed between the second-second light blocking pattern 663b and the second-third light blocking pattern 663c.

The first to third slits S1, S2, and S3 may be formed to have different widths. More specifically, the second slit S2 may have a greater width than the first slit S1, and the third slit S3 may have a greater width than the second slit S2. However, the present specification is not limited thereto.

For example, the width of the first slit S1, the width of the second slit S2, and the width of the third slit S3 may be similar to one another and may be defined as ranging from about 1:3:7 to 1:5:10. However, the present specification is not necessarily limited thereto.

More specifically, the size of the width of the first slit S1 may range from about 1 to 3 μm, the size of the width of the second slit S2 may range from about 3 μm to 15 μm, and the size of the width of the third slit S3 may range from 7 μm to 50 μm. However, the widths of the slits are not necessarily limited thereto.

Next, an exposure process of irradiating the organic film 150 with light is performed using a photolithography technique through the exposure mask 660. Here, during the exposure process, while light is blocked by the first light blocking pattern 661 provided on the exposure mask 660, light is transmitted through the first to third slits S1, S2, and S3 of the light transmitting part LT, and the organic film 150 may be irradiated with the light.

In particular, the organic film 150 may be irradiated with the light through the first to third slits S1, S2, and S3 between the second-first to second-third light blocking patterns 663a, 663b, and 663c constituting the light transmitting part LT. Here, an area irradiated with the light may be the etching area EA of the organic film 150.

Then, referring to FIG. 11B, by developing and removing the exposed portion of the organic film 150 that is located in the etching area EA, the first to third etching patterns 153a, 153b, and 153c may be formed in the etching area EA of the organic film 150 that overlaps the first to third slits S1, S2, and S3 of the exposure mask 660. The first to third etching patterns 153a, 153b, and 153c may each include one or more etching patterns. However, the present specification is not limited thereto.

Moreover, the first to third etching holes 155a, 155b, and 155c may be formed between the first to third etching patterns 153a, 153b, and 153c.

The first etching hole 155a may be formed between the first etching pattern 153a and the portion of the organic film 150 located in the display panel area DPA, and the second etching hole 155b may be formed between the first etching pattern 153a and the second etching pattern 153b. In addition, the third etching hole 155c may be formed between the second etching pattern 153b and the third etching pattern 153c.

More specifically, the second etching hole 155b may have a greater width than the first etching hole 155a, and the third etching hole 155c may have a greater width than the second etching hole 155b. However, the present specification is not necessarily limited thereto.

For example, the width of the first etching hole 155a, the width of the second etching hole 155b, and the width of the third etching hole 155c may be similar to one another and may be defined as ranging from at least 1:3:7 to 1:5:10. However, the present specification is not necessarily limited thereto.

More specifically, the size of the width of the first etching hole 155a may range from about 1 μm to 3 μm, the size of the width of the second etching hole 155b may range from about 3 μm to 15 μm, and the size of the width of the third etching hole 155c may range from 7 to 50 μm. However, the widths of the etching holes are not necessarily limited thereto.

Next, referring to FIG. 11C, by performing a wet etching process, an etchant is introduced into the first to third etching holes 155a, 155b, and 155c between the first to third etching patterns 153a, 153b, and 153c to etch the substrate 110 located in the etching area EA.

Here, the differences in width of the first to third etching holes 155a, 155b, and 155c are for adjusting an etching cross-sectional shape of an etching surface of the substrate 110 by varying the inflow amount, the inflow speed, and the like of an etchant penetrating the substrate 110. In addition, finally, due to etching of the substrate 110, only the first and second etching patterns 153a and 153b may remain. The present specification is not limited thereto.

In this way, through the wet etching process using an etchant, a cross-sectional structure having a forward-tapered shape may be formed on the etching surface 113 of the substrate 110 of the etching area EA.

Accordingly, since the first to third etching holes 155a, 155b, and 155c are configured to have widths of different sizes, the degree to which the etching surface 113 located in the etching area EA of the substrate 110 is etched may be different on an upper portion and a lower portion thereof.

Specifically, the amount of etchant penetrating the substrate 110 through the second etching hole 155b may be greater than the amount of etchant penetrating the substrate 110 through the first etching hole 155a having a smaller width, and the amount of etchant introduced through the third etching hole 155c may be greater than the amount of etchant introduced through the second etching hole 155b.

Accordingly, since the speed of isotropic etching gradually decreases from the upper portion toward the lower portion in relation to the degree to which the etching surface 113 of the substrate 110 is etched, a cross-section having a forward-tapered shape may be formed.

In addition, fabrication methods according to different embodiments of an etching cross-sectional structure of a substrate of a display device of the present specification will be described.

FIGS. 12A to 12C are cross-sectional views showing a process of etching a substrate of the display panel according to the second embodiment of the present specification.

In FIGS. 12A to 12C, for convenience of description, a substrate 110 is illustrated instead of the display panel 100, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on the substrate 110, are not excluded.

Hereinafter, the substrate 110 may refer to a glass substrate on which the circuit device layer 122, the light-emitting device layer 124, and the encapsulation layer 126 are provided.

Referring to FIG. 12A, after entirely etching the other surface of the substrate 110, the organic film 150 is formed on the other surface of the substrate 110 in a state in which the substrate 110 is flipped upside down so that the other surface faces upward.

Specifically, the organic film 150 is formed by applying an organic material on the entire other surface of the substrate 110. Here, the organic material forming the organic film 150 may be a colorless, transparent material, but the present specification is not necessarily limited thereto. In addition, the material forming the organic film may also be a colored organic material. The material forming the organic film may be applied on the other surface of the substrate 110 using a screen printer, but the present specification is not necessarily limited thereto.

Next, an exposure mask 160 is disposed on an upper side of the organic film 150 at a predetermined distance.

Here, the exposure mask 160 may include a light blocking part LB and a light transmitting part LT. The light blocking part LB of the exposure mask 160 may be located to overlap a plurality of display panel areas DPA, and the light transmitting part LT may be located to overlap etching areas EA between the plurality of display panel areas DPA. Here, a portion of the etching areas EA may overlap a portion of each of the plurality of display panel areas DPA. However, the present specification is not necessarily limited thereto.

The exposure mask 160 may include a transparent substrate 160a, a first light blocking pattern 161, and second-first to second-fourth light blocking patterns 163a, 163b, 163c, and 163d including a plurality of slits S1, S2, S3, and S4.

Moreover, the first light blocking pattern 161 may be provided on the light blocking part LB of the exposure mask 160, and the second-first to second-fourth light blocking patterns 163a, 163b, 163c, and 163d may be provided on the light transmitting part LT. Here, first to fourth slits S1, S2, S3, and S4 may be formed between the second-first to second-fourth light blocking patterns 163a, 163b, 163c, and 163d. Here, the first to fourth slits S1, S2, S3, and S4 may adjust the intensity of a transmissive light source to adjust line widths of the second-first, second-second, second-third, and second-fourth light blocking patterns 163a, 163b, 163c, and 163d. In addition, the second-first to second-fourth light blocking patterns 163a, 163b, 163c, and 163d may each include one or more light blocking patterns, but the present specification is not limited thereto.

The first slit S1 may be formed between the first light blocking pattern 161 and the second-first light blocking pattern 163a, and the second slit S2 may be formed between the second-first light blocking pattern 163a and the second-second light blocking pattern 163b. Further, the third slit S3 may be formed between the second-second light blocking pattern 163b and the second-third light blocking pattern 163c. In addition, the fourth slit S4 may be formed between the second-third light blocking pattern 163c and the second-fourth light blocking pattern 163d.

A slit width may be formed to gradually increase from the first slit S1 toward the fourth slit S4. More specifically, the second slit S2 may have a greater width than the first slit S1, the third slit S3 may have a greater width than the second slit S2, and the fourth slit S4 may have a greater width than the third slit S3. However, the present specification is not limited thereto.

For example, a ratio of the width of the first slit S1 to the width of the second slit S2 to the width of the third slit S3 to the width of the fourth slit S4 may be defined as ranging from about 1:3:5:7 to 1:5:10:15. However, the present specification is not necessarily limited thereto. Specifically, the width of the first slit S1 may range from about 1 to 3 μm, the width of the second slit S2 may range from about 3 to 5 μm, the width of the third slit S3 may range from 5 to 10 μm, and the width of the fourth slit S4 may range from 7 to 20 μm. However, the present specification is not necessarily limited thereto.

Next, an exposure process of irradiating the organic film 150 with light is performed using a photolithography technique through the exposure mask 160. Here, during the exposure process, while light is blocked by the first light blocking pattern 161 provided on the exposure mask 160, a portion of light is transmitted through the first to fourth slits S1, S2, S3, and S4 of the light transmitting part LT, and the organic film 150 may be irradiated with the light.

In particular, the organic film 150 may be irradiated with the light through the first to fourth slits S1, S2, S3, and S4 between the second-first to second-fourth light blocking patterns 163a, 163b, 163c, and 163d constituting the light transmitting part LT. Here, an area irradiated with the light may be the etching area EA of the organic film 150.

Then, referring to FIG. 12B, by developing and removing the exposed portion of the organic film 150 that is located in the etching area EA, the first to fourth etching patterns 153a, 153b, 153c, and 153d may be formed in the etching area EA of the organic film 150. Here, the first to fourth etching patterns 153a, 153b, 153c, and 153d may be formed at positions overlapping the first to fourth slits S1, S2, S3, and S4 of the exposure mask 160. The first to fourth etching patterns 153a, 153b, 153c, and 153d may each include one or more etching patterns. However, the present specification is not limited thereto.

Moreover, first to fourth etching holes 155a, 155b, 155c, and 155d may be formed between the first to fourth etching patterns 153a, 153b, 153c, and 153d.

The first etching hole 155a may be formed between the first etching pattern 153a and an etching surface on the portion of the organic film 150 located in the display panel area DPA, and the second etching hole 155b may be formed between the first etching pattern 153a and the second etching pattern 153b. In addition, the third etching hole 155c may be formed between the second etching pattern 153b and the third etching pattern 153c. Further, the fourth etching hole 155d may be formed between the third etching pattern 153c and the fourth etching pattern 153d.

More specifically, a width may be formed to gradually increase from the first etching hole 155a toward the fourth etching hole 155d. For example, the second etching hole 155b may have a greater width than the first etching hole 155a, and the third etching hole 155c may have a greater width than the second etching hole 155b. In addition, the fourth etching hole 155d may have a greater width than the third etching hole 155c. However, the present specification is not necessarily limited thereto.

For example, the width of the first etching hole 155a to the width of the second etching hole 155b to the width of the third etching hole 155c to the width of the fourth etching hole 155d may be defined as ranging from about 1:3:5:7 to 1:5:7:15. However, the present specification is not necessarily limited thereto. More specifically, the width of the first etching hole 155a may range from about 1 μm to 3 μm, the width of the second etching hole 155b may range from about 3 μm to 5 μm, the width of the third etching hole 155c may range from 5 μm to 10 μm, and the width of the fourth etching hole 155d may range from about 7 μm to 20 μm. However, the widths of the etching holes are not necessarily limited thereto.

Next, referring to FIG. 12C, an etchant is introduced into the first to fourth etching holes 155a, 155b, 155c, and 155d between the first to fourth etching patterns 153a, 153b, 153c, and 153d of the organic film 150 so that the etchant penetrates the substrate 110 below the organic film 150, and isotropic etching is performed. Here, due to performing etching of the substrate 110, finally, only the first etching pattern 153a may remain. However, the present specification is not limited thereto.

The differences in width of the first to fourth etching holes 155a, 155b, 155c, and 155d are for adjusting an etching cross-sectional shape of an etching surface of the substrate 110 by varying the inflow amount, the inflow speed, and the like of an etchant penetrating the substrate 110.

Moreover, the etching surface 113 of the glass substrate 110 located in the etching area EA may, after isotropic etching is performed, finally include the forward-tapered side 113a, the vertical side 113b, and the reverse-tapered side 113c. Here, the forward-tapered side 113a, the vertical side 113b, and the reverse-tapered side 113c may constitute the etching surface 113 that is round.

The forward-tapered side 113a and the reverse tapered-side 113c may be formed at positions overlapping the first and second slits S1 and S2 of the organic film 150, and the vertical side 113b may be formed to extend between the forward-tapered side 113a and the reverse-tapered side 113c. However, the present specification is not necessarily limited thereto. In addition, the third and fourth etching patterns 153c and 153d of the organic film 150 may be removed during the etching process. However, the present specification is not necessarily limited thereto.

In particular, the third etching pattern 153c of the organic film 150 or the third and fourth etching patterns 153c and 153d of the organic film 150 may be finally removed after the etching process. However, the present specification is not necessarily limited thereto. According to another embodiment, one or more of the first to fourth etching patterns 153a, 153b, 153c, and 153d may remain even after the etching process.

More specifically, since the amount of etchant introduced into the substrate 110 gradually increases through the first to fourth etching holes 155a, 155b, 155c, and 155d of the organic film 150, and etching of an etching surface in the etching area EA of the substrate 110 is isotropically performed, the etching surface 113 of the substrate 110 in the etching area EA has a cross-section having a rounded shape. For example, the etching surface 113 of the substrate 110 that is located below the first etching hole 155a and the second etching hole 155b may include the forward-tapered side 113a, the vertical side 113b, and the reverse-tapered side 113c. For example, the upper portion of the etching surface 113 may have the forward-tapered side 113a, the central portion of the etching surface 113 may have the vertical side 113b, and the lower portion of the etching surface 113 may have the reverse-tapered side 113c.

As a result, since the amount of etchant introduced gradually increases from the first to fourth etching holes 155a, 155b, 155c, and 155d, whose widths gradually increase in that order, the speed at which the etching surface 113 of the substrate 110 is etched may vary.

Accordingly, due to performing wet etching using an etchant, the etching surface 113 of the substrate 110 may have a rounded cross-section that has the forward-tapered side 113a, the vertical side 113b, and the reverse-tapered side 113c.

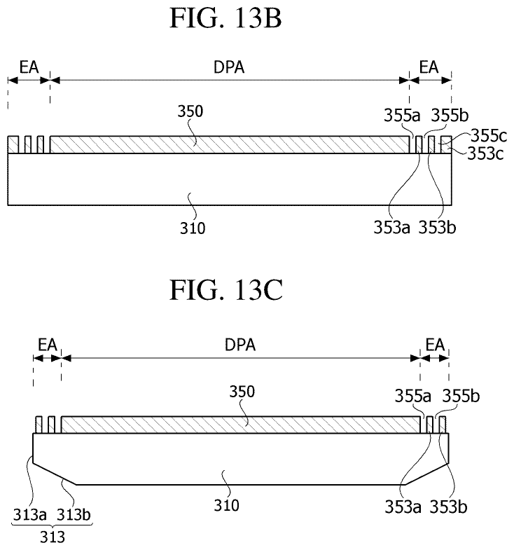

FIGS. 13A to 13C are cross-sectional views showing a process of etching a substrate of the display panel according to the third embodiment of the present specification.

In FIGS. 13A to 13C, for convenience of description, a substrate 310 is illustrated instead of the display panel 100, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on one surface of the substrate 310, are not excluded.

Hereinafter, the substrate 310 may refer to a glass substrate on which the circuit device layer 122, the light-emitting device layer 124, and the encapsulation layer 126 are provided.

Referring to FIG. 13A, after entirely etching the other surface of the substrate 310, the organic film 350 is formed on the other surface of the substrate 310 in a state in which the substrate 310 is flipped upside down so that the other surface is located at an upper portion.

Specifically, the organic film 350 is formed by applying an organic material on the entire other surface of the substrate 310. Here, the organic material forming the organic film 350 may be a colorless, transparent material, but the present specification is not necessarily limited thereto. In addition, the material forming the organic film may also be a colored organic material. The material forming the organic film may be applied on the other surface of the substrate 310 using a screen printer, but the present specification is not necessarily limited thereto.

Next, an exposure mask 360 is disposed on an upper side of the organic film 350 at a predetermined distance.

Here, the exposure mask 360 may include a light blocking part LB and a light transmitting part LT. The light blocking part LB of the exposure mask 360 may be located to overlap a plurality of display panel areas DPA, and the light transmitting part LT may be located to overlap etching areas EA between the plurality of display panel areas DPA. Here, a portion of the etching areas EA may overlap a portion of each of the plurality of display panel areas DPA.

The exposure mask 360 may include a transparent substrate 360a, a first light blocking pattern 361, and second-first to second-third light blocking patterns 363a, 363b, and 363c including a plurality of slits S1, S2, and S3.

The first light blocking pattern 361 may be provided on the light blocking part LB of the exposure mask 360, and the second-first to second-third light blocking patterns 363a, 363b, and 363c may be provided on the light transmitting part LT. Here, first to third slits S1, S2, and S3 may be formed between the second-first to second-third light blocking patterns 363a, 363b, and 363c. Here, the first to third slits S1, S2, and S3 may adjust the intensity of a transmissive light source to adjust line widths of the second-first, second-second, and second-third light blocking patterns 363a, 363b, and 363c. In addition, the second-first to second-third light blocking patterns 363a, 363b, and 363c may each include one or more light blocking patterns, but the present specification is not limited thereto.

The first slit S1 may be formed between the first light blocking pattern 361 and the second-first light blocking pattern 363a, and the second slit S2 may be formed between the second-first light blocking pattern 363a and the second-second light blocking pattern 363b. Further, the third slit S3 may be formed between the second-second light blocking pattern 363b and the second-third light blocking pattern 363c.

The widths of the first to third slits S1, S2, and S3 may be the same or slightly different from each other. However, the present specification is not limited thereto.

For example, a ratio of the width of the first slit S1 to the width of the second slit S2 to the width of the third slit S3 may be defined as ranging from about 1:1:1 to 1:1.5:2. However, the present specification is not necessarily limited thereto. Specifically, the width of the first slit S1 may range from about 1 μm to 5 μm, the width of the second slit S2 may range from about 1 μm to 7 μm, and the width of the third slit S3 may range from 1 μm to 10 μm. However, the present specification is not necessarily limited thereto.

Next, an exposure process of irradiating the organic film 350 with light is performed using a photolithography technique through the exposure mask 360. Here, during the exposure process, while light is blocked by the first light blocking pattern 361 provided on the exposure mask 360, light is transmitted through the first to third slits S1, S2, and S3 of the light transmitting part LT, and the organic film 350 may be irradiated with the light.

In particular, the organic film 350 may be irradiated with the light through the first to third slits S1, S2, and S3 between the second-first to second-third light blocking patterns 363a, 363b, and 363c constituting the light transmitting part LT. Here, an area irradiated with the light may be the etching area EA of the organic film 350.

Then, referring to FIG. 13B, by developing and removing the exposed portion of the organic film 350 that is located in the etching area EA, the first to third etching patterns 353a, 353b, and 353c may be formed at positions overlapping the first to third slits S1, S2, and S3 of the exposure mask 360 in the etching area EA of the organic film 350. The first to third etching patterns 353a, 353b, and 353c may each include one or more etching patterns. However, the present specification is not limited thereto.

Moreover, first to third etching holes 355a, 355b, and 355c may be formed between the first to third etching patterns 353a, 353b, and 353c.

The first etching hole 355a may be formed between the first etching pattern 353a and an etching surface on the portion of the organic film 350 located in the display panel area DPA, and the second etching hole 355b may be formed between the first etching pattern 353a and the second etching pattern 353b. In addition, the third etching hole 355c may be formed between the second etching pattern 353b and the third etching pattern 353c.

Here, the first to third etching patterns 353a, 353b, and 353c may each include one or more etching patterns. However, the present specification is not limited thereto.

Further, the first to third etching holes 355a, 355b, and 355c may be formed between the first to third etching patterns 353a, 353b, and 353c.

Specifically, the first etching hole 355a may be formed between the first etching pattern 353a and the portion of the organic film 350 located in the display panel area DPA, and the second etching hole 355b may be formed between the first etching pattern 353a and the second etching pattern 353b. In addition, the third etching hole 355c may be formed between the second etching pattern 353b and the third etching pattern 353c.

More specifically, the first etching hole 355a, the second etching hole 355b, and the third etching hole 355c may have widths of similar sizes. However, the present specification is not necessarily limited thereto.

For example, a ratio of the width of the first etching hole 355a to the width of the second etching hole 355b to the width of the third etching hole 355c may range from about 1:1:1 to 1:1.5:2. However, the present specification is not necessarily limited thereto.

More specifically, the size of the width of the first etching hole 355a may range from about 1 μm to 5 μm, the size of the width of the second etching hole 355b may range from about 1 μm to 7 μm, and the size of the width of the third etching hole 355c may range from 1 μm to 10 μm. However, the widths of the etching holes are not necessarily limited thereto.

Such a difference in width between the first to third etching holes 355a, 355b, and 355c is for adjusting an etching cross-sectional shape of an etching surface of the glass substrate 310 by varying the inflow amount, the inflow speed, and the like of an etchant penetrating the glass substrate 310.

Here, since the first to third etching holes 355a, 355b, and 355c are configured to have widths of similar sizes, the degree to which the etching surface 313 located in the etching area EA of the substrate 310 is etched may only be slightly different on an upper portion and a lower portion.

Next, referring to FIG. 13C, an etchant is introduced into the first to third etching holes 355a, 355b, and 355c between the first to third etching patterns 353a, 353b, and 353c of the organic film 350 so that the etchant penetrates the substrate 310 below the organic film 350, and isotropic etching is performed.

In this way, through the etching process, since the amount of etchant penetrating the substrate 310 through the first to third etching holes 355a, 355b, and 355c that have a small width is small, and the speed thereof is slow, a vertical side 313a may be formed on the upper portion of the etching surface 313 of the substrate 310, and a reverse-tapered side 313b may be formed on the lower portion of the etching surface 313 of the substrate 310. Here, due to etching of the substrate 310, only the first and second etching patterns 353a and 353b may remain. The present specification is not limited thereto.

Accordingly, since an etchant is introduced in similar amounts into the first to third etching holes 355a, 355b, and 355c, the etching surface 313 of the substrate 310 may simultaneously have the vertical side 313a and the reverse-tapered side 313b due to performing wet etching using the etchant as the etchant is introduced through the first to third etching holes 355a, 355b, and 355c.

Here, the third etching pattern 353c may be removed as a portion of the substrate 310 is etched during the wet etching process. However, the present specification is not necessarily limited thereto. Specifically, at least one of the first to third etching patterns 353a, 353b, and 353c may be removed during the wet etching process.

FIGS. 14A to 14C are cross-sectional views showing a process of etching a substrate of the display panel according to the fourth embodiment of the present specification.

In FIGS. 14A to 14C, for convenience of description, a substrate 410 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on one surface of the substrate 410, are not excluded.

Hereinafter, the glass substrate 410 may refer to a glass substrate on which the circuit device layer 122, the light-emitting device layer 124, and the encapsulation layer 126 are provided.

Referring to FIG. 14A, after entirely etching the other surface of the substrate 410, the organic film 450 is formed on the other surface of the substrate 410 in a state in which the substrate 410 is flipped upside down so that the other surface faces upward.

Specifically, the organic film 450 is formed by applying an organic material on the entire other surface of the substrate 410. Here, the organic material forming the organic film 450 may be a colorless, transparent material, but the present specification is not necessarily limited thereto. In addition, the material forming the organic film may also be a colored organic material. The material forming the organic film may be applied on the other surface of the substrate 410 using a screen printer, but the present specification is not necessarily limited thereto.

Next, an exposure mask 460 is disposed on an upper side of the organic film 450 at a predetermined distance.

Here, the exposure mask 460 may include a light blocking part LB and a light transmitting part LT. The light blocking part LB of the exposure mask 460 may be located to overlap a plurality of display panel areas DPA, and the light transmitting part LT may be located to overlap etching areas EA between the plurality of display panel areas DPA. Here, a portion of the etching areas EA may overlap a portion of each of the plurality of display panel areas DPA.

The exposure mask 460 may include a transparent substrate 460a, a first light blocking pattern 461, and second-first and second-second light blocking patterns 463a and 463b including a plurality of slits S1 and S2.

Moreover, the first light blocking pattern 461 may be provided on the light blocking part LB of the exposure mask 460, and the second-first and second-second light blocking patterns 463a and 463b may be provided on the light-transmitting part LT. Here, first and second slits S1 and S2 may be formed between the second-first and second-second light blocking patterns 463a and 463b. Here, the first and second slits S1 and S2 may adjust the intensity of a transmissive light source to adjust line widths of the second-first and second-second light blocking patterns 463a and 463b. Further, the second-first and second-second light blocking patterns 463a and 463b may each include one or more light blocking patterns, but the present specification is not limited thereto.

The first slit S1 may be formed between the first light blocking pattern 461 and the second-first light blocking pattern 463a, and the second slit S2 may be formed between the second-first light blocking pattern 463a and the second-second light blocking pattern 463b.

The widths of the first slit S1 and the second slit S2 may be formed to be different from each other. More specifically, the second slit S2 may have a greater width than the first slit S1. However, the present specification is not limited thereto.

For example, a ratio of the width of the first slit S1 to the width of the second slit S2 may be defined as ranging from about 1:5 or more. However, the present specification is not necessarily limited thereto. Specifically, the width of the first slit S1 may range from about 1 to 5 μm, and the width of the second slit S2 may range from about 5 to 30 μm. However, the present specification is not necessarily limited thereto.

Next, an exposure process of irradiating the organic film 450 with light is performed using a photolithography technique through the exposure mask 460. Here, during the exposure process, while light is blocked by the first light blocking pattern 461 provided on the exposure mask 460, light is transmitted through the first and second slits S1 and S2 of the light transmitting part LT, and the organic film 450 may be irradiated with the light.

In particular, the organic film 450 may be irradiated with the light through the first and second slits S1 and S2 between the second-first and second-second light blocking patterns 463a and 463b constituting the light transmitting part LT. Here, an area irradiated with the light may be the etching area EA of the organic film 450.

Then, referring to FIG. 14B, by developing and removing the exposed portion of the organic film 450 that is located in the etching area EA, first and second etching patterns 453a and 453b may be formed at positions overlapping the first and second slits S1 and S2 of the exposure mask 460 in the etching area EA of the organic film 450.

Here, the first and second etching patterns 453a and 453b may each include one or more etching patterns. However, the present specification is not limited thereto.

Moreover, first and second etching holes 455a and 455b may be formed between the first and second etching patterns 453a and 453b.

The first etching hole 455a may be formed between the first etching pattern 453a and the portion of the organic film 450 located in the display panel area DPA, and the second etching hole 455b may be formed between the first etching pattern 453a and the second etching pattern 453b.

More specifically, the width of the second etching hole 455b may be formed to be greater than the width of the first etching hole 455a. For example, a ratio of the width of the first etching hole 455a to the width of the second etching hole 455b may be about 1:5 or more. However, the present specification is not necessarily limited thereto.

Further, the width of the first etching hole 455a may range from about 1 μm to 5 μm, and the width of the second etching hole 455b may range from about 5 to 30 μm. However, the widths of the etching holes are not necessarily limited thereto.

Such a difference in width between the first etching hole 455a and the second etching hole 455b is for adjusting an etching cross-sectional shape of an etching surface of the substrate 410 by varying the inflow amount, the inflow speed, and the like of an etchant penetrating the glass substrate 410.

Referring to FIG. 14C, by performing the wet etching process, an etchant is introduced into the first and second etching holes 455a and 455b between the first and second etching patterns 453a and 453b to etch the substrate 410. Here, the amount of etchant introduced into the substrate 410 through the second etching hole 455b of the organic film 450 is greater than the amount of etchant introduced into the substrate 410 through the first etching hole 455a.

As a result, since etching of an etching surface in the etching area EA of the glass substrate 410 is isotropically performed more rapidly through the second etching hole 455b than through the first etching hole 455a, the etching surface 413 of the substrate 410 in the etching area EA may include a cross-section having a steep reverse-tapered shape.

Here, after the etching process, the first etching pattern 453a of the organic film 450 may remain, and the second etching pattern 453b may be removed. However, the present specification is not limited thereto.

FIGS. 15A to 15C are cross-sectional views showing a process of etching a substrate of the display panel according to the fifth embodiment of the present specification.

In FIGS. 15A to 15C, for convenience of description, a substrate 510 is illustrated instead of the display panel 100 of FIG. 2, but a circuit device layer (not illustrated) (see 122 of FIG. 2), a light-emitting device layer (not illustrated) (see 124 of FIG. 2), and an encapsulation layer (not illustrated) (see 126 of FIG. 2), which are provided on one surface of the substrate 510, are not excluded.

Hereinafter, the substrate 510 may refer to a glass substrate on which the circuit device layer 122, the light-emitting device layer 124, and the encapsulation layer 126 are provided.

Referring to FIG. 15A, after entirely etching the other surface of the substrate 510, the organic film 550 is formed on the other surface of the substrate 510 in a state in which the substrate 510 is flipped upside down so that the other surface faces upward.

Specifically, the organic film 550 is formed by applying an organic material on the entire other surface of the substrate 510. Here, the organic material forming the organic film 550 may be a colorless, transparent material, but the present specification is not necessarily limited thereto. In addition, the material forming the organic film may also be a colored organic material. The material forming the organic film may be applied on the other surface of the substrate 510 using a screen printer, but the present specification is not necessarily limited thereto.

Next, an exposure mask 560 is disposed on an upper side of the organic film 550 at a predetermined distance.

Here, the exposure mask 560 may include a light blocking part LB and a light transmitting part LT. The light blocking part LB of the exposure mask 560 may be located to overlap a plurality of display panel areas DPA, and the light transmitting part LT may be located to overlap etching areas EA between the plurality of display panel areas DPA. Here, a portion of the etching areas EA may overlap a portion of each of the plurality of display panel areas DPA.

The exposure mask 560 may include a transparent substrate 560a, a first light blocking pattern 561, and second-first to second-fourth light blocking patterns 563a, 563b, 563c, and 563d including a plurality of slits S1, S2, S3, and S4.

Moreover, the first light blocking pattern 561 may be provided on the light blocking part LB of the exposure mask 560, and the second-first to second-fourth light blocking patterns 563a, 563b, 563c, and 563d may be provided on the light transmitting part LT. Here, first to fourth slits S1, S2, S3, and S4 may be formed between the second-first to second-fourth light blocking patterns 563a, 563b, 563c, and 563d. Here, the first to fourth slits S1, S2, S3, and S4 may adjust the intensity of a transmissive light source to adjust line widths of the second-first to second-fourth light blocking patterns 563a, 563b, 563c, and 563d. Further, the second-first to second-fourth light blocking patterns 563a, 563b, 563c, and 563d may each include one or more light blocking patterns, but the present specification is not limited thereto.

The first slit S1 may be formed between the first light blocking pattern 561 and the second-first light blocking pattern 563a, and the second slit S2 may be formed between the second-first light blocking pattern 563a and the second-second light blocking pattern 563b. In addition, the third slit S3 may be formed between the second-second light blocking pattern 563b and the second-third light blocking pattern 563c. Further, the fourth slit S4 may be formed between the second-third light blocking pattern 563c and the second-fourth light blocking pattern 563d.

The first to third slits S1, S2, and S3 may be formed to have the same width, and the width of the fourth slit S4 may be formed to be greater than the width of each of the first to third slits S1, S2, and S3. However, the present specification is not limited thereto.

For example, a ratio of the width of each of the first to third slits S1, S2, and S3 to the width of the fourth slit S4 may be about 1:3 or more. However, the present specification is not necessarily limited thereto. More specifically, the width of each of the first to third slits S1, S2, and S3 may range from about 1 μm to 5 μm, and the width of the fourth slit S4 may range from about 3 μm to 20 μm. However, the present specification is not necessarily limited thereto.

Next, an exposure process of irradiating the organic film 550 with light is performed using a photolithography technique through the exposure mask 560. Here, during the exposure process, while light is blocked by the first light blocking pattern 561 provided on the exposure mask 560, light is transmitted through the first to fourth slits S1, S2, S3, and S4 of the light transmitting part LT, and the organic film 550 may be irradiated with the light.

In particular, the organic film 550 may be irradiated with the light through the first to fourth slits S1, S2, S3, and S4 between the second-first to second-fourth light blocking patterns 563a, 563b, 563c, and 563d constituting the light transmitting part LT. Here, an area irradiated with the light may be the etching area EA of the organic film 550.

Then, referring to FIG. 15B, by developing and removing the exposed portion of the organic film 550 that is located in the etching area EA, first to fourth etching patterns 553a, 553b, 553c, and 553d may be formed at positions overlapping the first to fourth slits S1, S2, S3, and S4 of the exposure mask 560 in the etching area EA of the organic film 550. The first to fourth etching patterns 553a, 553b, 553c, and 553d may each include one or more etching patterns. However, the present specification is not limited thereto.

Next, first to fourth etching holes 555a, 555b, 555c, and 555d may be formed between the first to fourth etching patterns 553a, 553b, 553c, and 553d.

More specifically, the first etching hole 555a may be formed between the first etching pattern 553a and the portion of the organic film 550 located in the display panel area DPA, and the second etching hole 555b may be formed between the first etching pattern 553a and the second etching pattern 553b. In addition, the third etching hole 555c may be formed between the second etching pattern 553b and the third etching pattern 553c. Further, the fourth etching hole 555d may be formed between the third etching pattern 553c and the fourth etching pattern 553d.

More specifically, the widths of the first to third etching holes 555a, 555b, and 555c may be formed to have similar sizes, and the width of the fourth etching hole 555d may be formed to be greater than the width of each of the first to third etching holes 555a, 555b, and 555c.

For example, a ratio of the width of each of the first to third etching holes 555a, 555b, and 555c to the width of the fourth etching hole 555d may be about 1:3 or more. However, the present specification is not necessarily limited thereto.

Moreover, the width of each of the first to third etching holes 555a, 555b, and 555c may range from about 1 to 5 μm, and the width of the fourth etching hole 555d may range from about 3 to 20 μm. However, the widths of the etching holes are not necessarily limited thereto.

Such a difference in width between the first to third etching holes 555a, 555b, and 555c and the fourth etching hole 555d is for adjusting an etching cross-sectional shape of an etching surface of the substrate 510 by varying the inflow amount, the inflow speed, and the like of an etchant penetrating the substrate 510.

Then, referring to FIG. 15C, by performing a wet etching process, an etchant is introduced into the first to fourth etching holes 555a, 555b, 555c, and 555d between the first to fourth etching patterns 553a, 553b, 553c, and 553d to etch the substrate 510 located in the etching area EA. Here, due to etching of the substrate 510, only the first to third etching patterns 553a, 553b, and 553c may remain. However, the present specification is not limited thereto.

More specifically, in FIG. 15C, the amount of etchant introduced into the substrate 510 through the fourth etching hole 555d of the organic film 550 is greater than the amount of etchant introduced through the first to third etching holes 555a, 555b, and 555c. As a result, since etching of an etching surface in the etching area EA of the substrate 510 is more isotropically performed through the fourth etching hole 555d than through the first to third etching holes 555a, 555b, and 555c, the etching surface 513 of the substrate 510 in the etching area EA may have a cross-section including a forward-tapered side 513a, a vertical side 513b, and a reverse-tapered side 513c. Further, the reverse-tapered side 513c may be inclined at a greater angle than the forward-tapered side 513a.

In this way, in a display device according to the present specification, by adjusting the widths of etching holes between a plurality of etching patterns when performing a wet etching process, an etching surface of a substrate may have various shapes such as, a rounded surface shape including a vertical side and a tapered side, a reverse-tapered shape, or a forward-tapered shape.

Accordingly, in the display device according to the present specification, by etching an organic film disposed on the other surface of the substrate to form a plurality of etching patterns, and then using the etching patterns as etching masks to etch a portion of the substrate that is located in an etching area, precision with respect to etching positions on the substrate can be improved in comparison to a laser process.

In the display device according to the present specification, by forming a side coating film on an etching surface of a substrate, light leakage can be prevented or reduced, and edges of a display panel can be prevented or obviated from being visible.

In the display device according to the present specification, since it is possible to control an etching surface of a substrate by adjusting the widths of etching holes between etching patterns of an organic film, the stiffness of the etching surface of the substrate can be improved, and accidents in which a worker is injured by a sharp etching surface can be prevented or reduced.

In the display device according to the present specification, by forming an organic film on the other surface of a substrate to define an etching area for cutting the substrate, damage to the substrate can be prevented or reduced, and transmission of external impact to a display panel can be prevented or reduced.

Moreover, in the display device according to the present specification, since an organic film having a plurality of etching patterns is formed on the other surface of a substrate and thus it is not necessary to form a separate side coating film, the fabrication process and costs can be reduced.

According to the present specification, by forming a plurality of etching patterns on an organic film disposed on the other surface of a substrate and then using the etching patterns as etching masks to etch a portion of the substrate that is located in an etching area, precision with respect to etching positions on the substrate can be improved in comparison to a laser process.

According to the present specification, by forming a side coating film on an etching surface of a substrate, light leakage can be prevented or reduced, and edges of a display panel can be prevented or reduced from being visible.

Moreover, according to the present specification, since it is possible to control an inclined form of an etching surface of a substrate by adjusting a width of an etching hole between etching patterns formed on an organic film, the stiffness of the etching surface of the substrate can be improved, and accidents in which a worker is injured by a sharp etching surface can be prevented or reduced.

According to the present specification, by forming an organic film on the other surface of a substrate to define an etching area for cutting the substrate, damage to the substrate can be prevented or reduced, and transmission of external impact to a display panel can be prevented or reduced.

Moreover, according to the present specification, since an organic film having a plurality of etching patterns is formed on the other surface of a substrate and thus it is not necessary to form a separate side coating film, the fabrication process and costs can be reduced.

The display device according to embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical apparatuses, desktop personal computers (PCs), laptop PCs, netbook computers, workstations, navigation apparatuses, automotive display apparatuses, theater displays, televisions (TVs), wallpaper apparatuses, signage apparatuses, notebook computers, monitors, cameras, camcorders, home appliances, and the like. In addition, a display device and a method of fabricating the same according to one or more embodiments of the present disclosure may be applied to various types of display devices such as an organic light-emitting lighting device or an inorganic light-emitting lighting device, and the present disclosure is not limited thereto.

A display device according to one or more embodiments of the present disclosure may be described as follows.

A display device according to one or more embodiments of the present disclosure may comprise a substrate having a plurality of pixels disposed on one surface and including an etching surface, an organic film disposed on the other surface of the substrate and including a plurality of etching patterns, and a side coating film disposed on the etching surface of the substrate.

The etching surface of the substrate may have a tapered end surface, and the side coating film may cover the tapered end surface of the etching surface.

The plurality of etching patterns of the organic film may include at least two or more etching patterns.

The plurality of etching patterns may include first and second etching patterns, include first to third etching patterns, or include first to fourth etching patterns.

A first etching hole may be provided between a side end of the organic film and the first etching pattern, a second etching hole may be provided between the first etching pattern and the second etching pattern, and the first etching hole and the second etching hole may have widths of different sizes.

A ratio of the width of the first etching hole to the width of the second etching hole may be 1:5 or more, the width of the first etching hole may range from 1 to 5 μm, and the width of the second etching hole may range from 5 to 30 μm.

The first to third etching holes between a side end of the organic film and each of the first to third etching patterns may have widths of the same size or widths of different sizes.

A ratio of the widths of the first to third etching holes may range from 1:1:1 to 1:1.5:2, and the size of the width of the first etching hole may range from 1 to 5 μm, the size of the width of the second etching hole may range from 1 to 7 μm, and the size of the width of the third etching hole may range from 1 to 10 μm, or the ratio of the widths of the first to third etching holes may range from 1:3:7 to 1:5:10, and the size of the width of the first etching hole may range from 1 to 3 μm, the size of the width of the second etching hole may range from 3 to 15 μm, and the size of the width of the third etching hole may range from 7 to 50 μm.

The first to fourth etching holes may be provided between a side end of the organic film and each of the first to fourth etching patterns, and the first to fourth etching holes may have widths of different sizes, or the first to third etching holes have widths of the same size, and the fourth etching hole may have a width greater than the width of each of the first to third etching holes.

The widths of the first to fourth etching holes may be formed to gradually increase from the side end of the organic film toward an outer boundary portion, a ratio of the widths of the first to fourth etching holes may range from 1:3:5:7 to 1:5:10:15, and the width of the first etching hole may range from 1 to 3 μm, the width of the second etching hole may range from 3 to 5 μm, the width of the third etching hole may range from 5 to 10 μm, and the width of the fourth etching hole may range from 7 to 20 μm.

A ratio of the width of each of the first to third etching holes to the width of the fourth etching hole may be 1:3 or more, the width of each of the first to third etching holes may range from 1 to 5 μm, and the width of the fourth etching hole may range from 3 to 20 μm.

The etching surface of the substrate may include a forward-tapered side, a vertical side, and a reverse-tapered side, may include a vertical side and a reverse-tapered side, or may include a reverse-tapered side or a forward-tapered side.

At the reverse-tapered side, the vertical side, and the forward-tapered side that constitute the etching surface of the substrate, the reverse-tapered side may be inclined at a greater angle than the forward-tapered side.

The organic film and the side coating film may be made of the same material.

A method of fabricating a display device according to one or more embodiments of the present disclosure may comprise forming a plurality of display cells on one surface of a substrate, entirely etching the other surface of the substrate, forming an organic film on the other surface of the substrate, forming a plurality of etching patterns by patterning the organic film, forming an etching groove along an etching area by etching the substrate below the plurality of etching patterns, forming a side coating film on the etching groove, and cutting the side coating film provided on the etching groove.

The forming of the plurality of etching patterns may include forming the plurality of etching patterns on the organic film located in the etching area through a patterning process using an exposure mask having a plurality of light blocking patterns and slits disposed between the light blocking patterns, and simultaneously forming etching holes in between the plurality of etching patterns.

The plurality of etching patterns may include at least two or more etching patterns.

The etching holes may have widths of different sizes, or at least one etching hole has a greater width than the other etching holes.

The forming of the etching groove along the etching area by etching the substrate below the plurality of etching patterns may include forming an etching surface including the etching groove by introducing an etchant through the etching holes in between the plurality of etching patterns and isotropically etching the etching area of the substrate.

The etching surface may include a forward-tapered side, a vertical side, and a reverse-tapered side, includes a vertical side and a reverse-tapered side, or includes a reverse-tapered side or a forward-tapered side.

The effects of the present disclosure are not limited to the effects mentioned above, and other effects not mentioned may be clearly understood by those skilled in the art from the description of the claims.

While the embodiments have been described in detail above with reference to the accompanying drawings, the present disclosure is not necessarily limited to these embodiments, and various changes and modifications may be made without departing from the technical idea of the present disclosure. Accordingly, the embodiments disclosed herein are to be considered descriptive and not restrictive of the technical idea of the present disclosure, and the scope of the technical idea of the present disclosure is not limited by these embodiments. Therefore, the above-described embodiments should be understood to be exemplary and not limiting in any aspect.

What is claimed is:

1. A display device comprising:
a substrate having a plurality of pixels on one surface, the substrate including a side surface as an etching surface; and
an organic film on another surface opposite to the one surface of the substrate, the organic film including a plurality of etching patterns at a position corresponding to the etching surface.

2. The display device of claim 1, further comprising:
a side coating film on the etching surface of the substrate.

3. The display device of claim 2, wherein the organic film and the side coating film include a same material.

4. The display device of claim 2, wherein the etching surface of the substrate includes a tapered end surface and the side coating film covers the tapered end surface of the etching surface.

5. The display device of claim 2, further comprising:
a polarizer film on the substrate, the polarizer film having an end protruding past the substrate,
wherein the side coating film fills a step difference between the substrate and the polarizer film.

6. The display device of claim 5, wherein an etching prevention film is between the side coating film and the polarizer film.

7. The display device of claim 2, wherein the side coating film includes an organic material that absorbs light.

8. The display device of claim 1, wherein the plurality of etching patterns of the organic film include at least two or more etching patterns.

9. The display device of claim 8, wherein the plurality of etching patterns include a first etching pattern and a second etching pattern.

10. The display device of claim 9, wherein a first etching hole is between a side end of the organic film and the first etching pattern, a second etching hole is between the first etching pattern and the second etching pattern, and the first etching hole and the second etching hole have widths of different sizes.

11. The display device of claim 10, wherein a ratio of a width of the first etching hole to a width of the second etching hole is 1:5 or more, a width of the first etching hole ranges from 1 μm to 5 μm, and the width of the second etching hole ranges from 5 μm to 30 μm.

12. The display device of claim 8, wherein the plurality of etching patterns include a first etching pattern, a second etching pattern, and a third etching pattern, and
wherein a first etching hole is between a side end of the organic film and the first etching pattern, a second etching hole is between the first etching pattern and the second etching pattern, a third etching hole is between the second etching pattern and the third etching pattern, and the first etching hole to the third etching hole have widths of a same size or widths of different sizes.

13. The display device of claim 12, wherein a ratio of the widths of the first etching hole to the third etching hole ranges from 1:1:1 to 1:1.5:2, and a size of a width of the first etching hole ranges from 1 μm to 5 μm, a size of a width of the second etching hole ranges from 1 μm to 7 μm, and a size of a width of the third etching hole ranges from 1 μm to 10 μm, or
the ratio of the widths of the first etching hole to the third etching hole ranges from 1:3:7 to 1:5:10, and the size of the width of the first etching hole ranges from 1 μm to 3 μm, the size of the width of the second etching hole ranges from 3 μm to 15 μm, and the size of the width of the third etching hole ranges from 7 μm to 50 μm.

14. The display device of claim 8, wherein the plurality of etching patterns include a first etching pattern, a second etching pattern, a third etching pattern, and a fourth etching pattern,
wherein a first etching hole is between a side end of the organic film and the first etching pattern, a second etching hole is between the first etching pattern and the second etching pattern, a third etching hole is between the second etching pattern and the third etching pattern, and a fourth etching hole is between the third etching pattern and the fourth etching pattern, and
wherein the first etching hole to the fourth etching hole have widths of different sizes, or the first etching hole to the third etching hole have widths of a same size and the fourth etching hole has a width greater than the width of each of the first etching hole to the third etching hole.

15. The display device of claim 14, wherein the widths of the first etching hole to the fourth etching hole gradually increase from the side end of the organic film toward an outer boundary portion, a ratio of the widths of the first etching hole to the fourth etching hole ranges from 1:3:5:7 to 1:5:10:15, and the width of the first etching hole ranges from 1 μm to 3 μm, the width of the second etching hole ranges from 3 μm to 5 μm, the width of the third etching hole ranges from 5 μm to 10 μm, and the width of the fourth etching hole ranges from 7 μm to 20 μm.

16. The display device of claim 14, wherein a ratio of the width of each of the first etching hole to the third etching hole to the width of the fourth etching hole is 1:3 or more, the width of each of the first etching hole to the third etching hole ranges from 1 μm to 5 μm, and the width of the fourth etching hole ranges from 3 μm to 20 μm.

17. The display device of claim 1, wherein the etching surface of the substrate includes a forward-tapered side, a vertical side, and a reverse-tapered side, includes a vertical side and a reverse-tapered side, or includes a reverse-tapered side or a forward-tapered side.

18. The display device of claim 17, wherein at the reverse-tapered side, the vertical side, and the forward-tapered side that constitute the etching surface of the substrate, the reverse-tapered side is inclined at a greater angle than the forward-tapered side.

19. A method of fabricating a display device, the method comprising:
forming a plurality of display cells on one surface of a substrate;
forming an organic film on another surface of the substrate that is opposite to the one surface of the substrate;
forming a plurality of etching patterns by patterning the organic film; and
forming an etching groove along an etching area by etching the substrate below the plurality of etching patterns.

20. The method of claim 19, further comprising:
forming a side coating film on the etching groove; and
cutting the side coating film provided on the etching groove.

21. The method of claim 19, wherein forming of the plurality of etching patterns includes forming the plurality of etching patterns on the organic film located in the etching area through a patterning process using an exposure mask having a plurality of light blocking patterns and slits that are between the plurality of light blocking patterns, and simultaneously forming etching holes in between the plurality of etching patterns.

22. The method of claim 21, wherein the plurality of etching patterns include at least two or more etching patterns.

23. The method of claim 22, wherein the etching holes have widths of different sizes, or at least one etching hole has a greater width than other etching holes from the etching holes.

24. The method of claim 21, wherein forming of the etching groove along the etching area by etching the substrate below the plurality of etching patterns includes forming an etching surface including the etching groove by introducing an etchant through the etching holes in between the plurality of etching patterns and isotropically etching the etching area of the substrate.

25. The method of claim 24, wherein the etching surface includes a forward-tapered side, a vertical side, and a reverse-tapered side, includes a vertical side and a reverse-tapered side, or includes a reverse-tapered side or a forward-tapered side.
